(19) United States
(12) Patent Application Publication
(10) Pub. No.: US 2023/0407454 A1
(43) Pub. Date: Dec. 21, 2023

(54) Multilayer Structure and Method for Producing Same, and Protective Sheet and Electronic Device which Utilize Same

(71) Applicant: Kuraray Co., Ltd., Okayama (JP)

(72) Inventors: Shuhei Kuzume, Kurashiki-shi, Okayama (JP); Tatsuya Oshita, Kurashiki-shi, Okayama (JP)

(73) Assignee: Kuraray Co., Ltd., Okayama (JP)

(21) Appl. No.: 18/035,298

(22) PCT Filed: Nov. 2, 2021
(86) PCT No.: PCT/JP2021/040462

§ 371 Date: May 4, 2023

(30) Foreign Application Priority Data
Nov. 4, 2020 (JP) 2020-184067

(51) Int. Cl. C23C 14/08; H01L 31/048; C23C 14/02; C23C 14/58

(52) U.S. Cl. CPC C23C 14/081; H01L 31/0481; C23C 14/025; C23C 14/5806

(57) ABSTRACT

The present disclosure relates to a multilayer structure including: a laminate including a base (X) and at least two layers (Y), the layers (Y) being provided on both faces of the base (X); and layers (Z) containing a thermoplastic resin.

### TECHNICAL FIELD

The present invention relates to a multilayer structure and a method for producing the same, and a protective sheet and an electronic device which utilize the same.

### BACKGROUND ART

Electronic devices such as solar cells and/or electronic instruments equipped with visual display units need to have transparent protective members capable of protecting surfaces. Of these electronic devices, flexible solar cells, as well as flexible displays have been used in recent years. In a flexible electronic device, since it is impossible to use a thick glass plate, a protective sheet which can substitute for the thick glass plate is necessary.

A protective sheet that is superior in barrier properties, particularly in water vapor barrier properties, must be used as a protective sheet which can substitute for a glass plate. With respect to such a protective sheet, for example, Patent Document 1 discloses that a multilayer structure which includes: a base (X) of PET or the lie; and a layer (Y) containing a reaction product of phosphoric acid with an aluminum-containing compound, in which an average particle diameter of the reaction product is 5 to 70 nm, can be used as a protective sheet which is superior in gas barrier properties and water vapor barrier properties and can maintain such performance even after a damp heat test.

### PRIOR ART DOCUMENTS

### Patent Documents

Patent Document 1: PCT International Publication No. 2016/103720

### SUMMARY OF THE INVENTION

### Problems to be Solved by the Invention

In recent years, water vapor barrier properties demanded for a protective sheet of an electronic device are extremely high, and there exist cases in which the conventional multilayer structures described above do not have sufficient water vapor barrier properties. Moreover, in flexible electronic devices, adhesiveness between a sealant of the electronic device and the protective sheet is important, and there may be a case in which high peel strength is desired for an electronic device obtained by laminating, with a sealant, an exposed surface of a protective sheet. Conceivable means may involve: laminating a plurality of films having water vapor barrier properties in order to satisfy the high required performance of the water vapor barrier properties; and laminating a film capable of enhancing peel strength with respect to a sealant on the exposed surface of the protective sheet in order to satisfy a high level of required performance of peel strength with respect to the sealant. However, the thickness of the protective sheet consequently becomes so great that flexibility may be impaired. In order to make the electronic device thin, although, for example, film-thinning of a member such as a sealant to be used in the electronic device has been also studied, a member being thin and having superior water vapor barrier properties, with superior adhesiveness with a sealant is strongly desired for the purpose of attaining a flexible electronic device having high quality.

The present invention was made in view of the foregoing circumstances, and an object of the present invention is to provide: a multilayer structure that has high levels of superiority in water vapor barrier properties and peel strength with respect to the sealant and is also superior in flexibility, and a method for producing the same; and a protective sheet and an electronic device which utilize the same.

### Means for Solving the Problems

According to the present invention, the aforementioned problems can be solved by providing any of the following:
(1) A multilayer structure including: a laminate including a base (X) and at least two layers (Y), the layers (Y) being provided on both faces of the base (X); and layers (Z) containing a thermoplastic resin as a principal component and being laminated via each of adhesive layers (I) on both faces of the laminate, in which the at least two layers (Y) contain a reaction product (D) of an inorganic phosphorus compound (BI) with a metal oxide (A) containing an aluminum atom; a thickness of the base (X) is 5 μm or more and 100 μm or less; a thickness of each layer of the layers (Z) is 5 μm or more and 100 μm or less; a total thickness of all layers is 15 μm or more and 120 μm or less; the at least two layers (Y) may be identical to or different from each other; the adhesive layers (I) provided on both faces of the laminate may be identical to or different from each other; the layers (Z) provided on both faces of the laminate may be identical to or different from each other; and a moisture permeability measured in accordance with ISO15106-5 is 1.0×10⁻² g/m²·day or less;
(2) The multilayer structure according to (1), wherein a thermal shrinkage percentage TS in an MD direction of the laminate when heated at 160° C. for 30 min is 1.0% or less;
(3) The multilayer structure according to (1) or (2), wherein with respect to thermal shrinkage percentages in an MD direction when heated at 160° C. for 30 min, a ratio (TS_{Z}/TS) of a thermal shrinkage percentage TS_{Z} of each of the layers (Z) to a thermal shrinkage percentage TS of the laminate is 2 or more;
(4) The multilayer structure according to any one of (1) to (3), further including an easily adhered layer (EA) laminated on at least one exposed surface side of the layers (Z);
(5) The multilayer structure according to (4), wherein the easily adhered layer (EA) contains an acrylic resin;
(6) The multilayer structure according to any one of (1) to (5), wherein the layers (Z) contain a polyester resin;
(7) A method for producing the multilayer structure according to any one of (1) to (6), the method including: a step (I) of forming precursor layers of the layers (Y) on both faces of the base (X) by applying a coating liquid (S) containing: a metal oxide (A) containing an aluminum atom; an inorganic phosphorus compound (BI); and a solvent, and removing the solvent; a step (II) of forming the layers (Y) by subjecting the precursor layers of the layers (Y) to a heat treatment; and a step (III) of laminating the layers (Z) via each of the adhesive layers (I), with the laminate obtained after the step (II) of forming the layers (Y);
(8) A protective sheet for an electronic device, the protective sheet including the multilayer structure according to any one of (1) to (6);
(9) The protective sheet according to (8), which is a protective sheet for protecting a surface of a photovoltaic device, an information display device, or an illuminating device;
(10) An electronic device including the protective sheet according to (8) or (9); and
(11) The electronic device according to (10), which is a flexible electronic device.

### Effects of the Invention

The present invention enables providing: a multilayer structure that is superior in water vapor barrier properties and peel strength with respect to the sealant at high levels and is also superior in flexibility, and a method for producing the same; and a protective sheet and an electronic device which utilize the same.

### BRIEF DESCRIPTION OF THE DRAWINGS

FIG. 1 is a partial cross sectional view showing an electronic device according to an embodiment of the present invention.

### DESCRIPTION OF EMBODIMENTS

As referred to herein, “barrier properties” predominantly mean both “oxygen barrier properties” and “water vapor barrier properties” (low moisture permeability), and the “gas barrier properties” predominantly mean “oxygen barrier properties”. The “peel strength” as referred to herein means peel strengths before and after a wet heat treatment described in EXAMPLES. Herein, layers provided in a plural number may be identical to or different from each other. As referred to herein, a “thickness” of each layer or the like means an average (average thickness) of measurements obtained at five arbitrary sites.

The multilayer structure of the present invention includes: a laminate including a base (X) and at least two layers (Y), the layers (Y) being provided on both faces of the base (X); and layers (Z) containing a thermoplastic resin as a principal component and being laminated via each of adhesive layers (I) on both faces of the laminate, in which the at least two layers (Y) contain a reaction product (D) of an inorganic phosphorus compound (BI) with a metal oxide (A) containing an aluminum atom; a thickness of the base (X) is 5 μm or more and 100 μm or less; a thickness of each layer of the layers (Z) is 5 μm or more and 100 μm or less; a total thickness of all layers is 15 μm or more and 120 μm or less; and a moisture permeability (water vapor transmission rate) measured in accordance with ISO15106-5:2015 is 1.0×10⁻² g/m²·day or less. The multilayer structure of the present invention tends to be prominently superior in the barrier properties due to having at least two layers (Y), the layers (Y) being provided on both faces of the base (X), and thus the moisture permeability tends to be easily adjusted to 1.0×10⁻² g/m²·day or less. In addition, the multilayer structure of the present invention tends to be prominently superior in the peel strength with respect to the sealant, due to the layers (Z) being laminated via each of the adhesive layers (I), on both faces of the laminate constituting the multilayer structure. Moreover, the multilayer structure of the present invention tends to be superior in flexibility, due to the total thickness of all layers being 15 μm or more and 120 μm or less. It is to be noted that, in general, when the layers (Z) are made thin, thermal shrinkage of the layers (Z) is likely to occur, and this results in an increase in a thermal shrinkage percentage of the multilayer structure, leading to a concern that the peel strength with respect to the sealant may lower. However, since the thermal shrinkage percentage of the laminate constituting the multilayer structure of the present invention can be typically small due to the presence of the layers (Y), which are resistant to thermal shrinkage, even if the layers (Z) are made thin, thermal shrinkage of the multilayer structure in which the layers (Z) are laminated to the laminate via each of the adhesive layers (I) is inhibited. Thus, the peel strength with respect to the sealant can be maintained even when the layers (Z) have been made thin. In addition, when the thermal shrinkage percentage of the layers (Z) falls within a certain range, peel strength is improved due to an anchoring effect; therefore, the layers (Z) preferably have the thermal shrinkage percentage being great to some extent. On the other hand, when the thermal shrinkage percentage of the layer (Z) is too great, the thermal shrinkage percentage of the multilayer structure increases, whereby lowering of the peel strength due to thermal shrinkage of the multilayer structure tends to be dominant, as compared with the improvement of the peel strength due to the anchoring effect. When the layer (Z) has a thickness of 5 μm or more, the effect of improving the peel strength may be sufficiently achieved due to the anchoring effect, because, for example, the thermal shrinkage percentage may fall within an appropriate range. For such reasons as those described above, the present invention is speculated to enable providing a multilayer structure that is superior in water vapor barrier properties and peel strength with respect to the sealant at high levels, even when a total thickness of all layers is 120 μm or less.

Base (X)

The base (X) is not particularly limited, and any of a variety of bases may be employed. A material of the base (X) is not particularly limited, and is exemplified by: resins such as a thermoplastic resin and a thermosetting resin; fiber assemblies such as a cloth and a paper; metal oxides; and the like. Of these, the thermoplastic resin or a fiber assembly is preferably contained, and the thermoplastic resin is more preferably contained. A shape of the base (X) is not particularly limited, and has preferably a layer shape such as a shape of a film or a sheet. The base (X) preferably includes a thermoplastic resin film or a paper, or a thermoplastic resin film in which an inorganic vapor deposition layer (X′) is provided, more preferably includes a thermoplastic resin film, and still more preferably is a thermoplastic resin film.

Examples of the thermoplastic resin used in the base (X) include: polyolefin resins such as polyethylene and polypropylene; polyester resins such as polyethylene terephthalate (PET), polyethylene-2,6-naphthalate, and polybutylene terephthalate, or copolymers thereof; polyamide resins such as nylon-6, nylon-66, and nylon-12; hydroxyl group-containing polymers such as polyvinyl alcohol and ethylene-vinyl alcohol copolymers; polystyrene; poly(meth)acrylic acid ester; polyacrylonitrile; polyvinyl acetate; polycarbonate; polyarylate; regenerated cellulose; polyimide; polyetherimide; polysulfone; polyethersulfone; polyetheretherketone; ionomer resins; and the like. The thermoplastic resin to be used in the base (X) is preferably at least one selected from the group consisting of polyethylene, polypropylene, polyethylene terephthalate, nylon-6, and nylon-66, and more preferably polyethylene terephthalate.

In the case in which the thermoplastic resin film is used as the base (X), the base (X) may be either a stretched film or an unstretched film. In order for the multilayer structure to be obtained have superior processing suitability (for printing, laminating, etc.), a stretched film, in particular, a biaxially stretched film, is preferred. The biaxially stretched film may be a biaxially stretched film produced by any method of simultaneous biaxial stretching, sequential biaxial stretching, and tubular stretching.

Examples of the paper which may be used as the base (X) include Kraft paper, pure paper, simili paper, glassine paper, parchment paper, synthetic paper, white board, manila board, milk-carton board, cup base paper, ivory paper, and the like.

The thermoplastic resin film in which the inorganic vapor deposition layer (X′) is provided, which may be used as the base (X), is typically a film having barrier properties against oxygen and/or water vapor, and is preferably a transparent film. As the thermoplastic resin film in which the inorganic vapor deposition layers (X′) are provided, which may be used for the thermoplastic resin film, the thermoplastic resin film, exemplified above as the above-described base (X), may be used. The inorganic vapor deposition layers (X′) may be formed by vapor deposition of an inorganic substance. Examples of the inorganic substance include metals (for example, aluminum), metal oxides (for example, silicon oxide, aluminum oxide), metal nitrides (for example, silicon nitride), metal nitride oxides (for example, silicon oxynitride), or metal carbonitrides (for example, silicon carbonitride), and the like. Of these, the inorganic vapor deposition layers (X′) formed of aluminum oxide, silicon oxide, magnesium oxide, or silicon nitride are preferred in light of superior transparency.

A procedure for forming the inorganic vapor deposition layer (X′) is not particularly limited and is exemplified by: physical vapor deposition such as a vacuum deposition (for example, resistance heating vapor deposition, electron beam vapor deposition, molecular beam epitaxy, etc.), sputtering, and ion plating; chemical vapor deposition such as thermal chemical vapor deposition (for example, catalyst chemical vapor deposition), photochemical vapor deposition, plasma chemical vapor deposition (for example, capacitively coupled plasma, inductively coupled plasma, surface wave plasma, electronic cyclotron resonance, dual magnetron, atom layer deposition, etc.), and organic metal vapor deposition.

The thickness of the inorganic vapor deposition layer (X′) may vary depending on the type of the component constituting the inorganic vapor deposition layer, and is preferably 0.002 to 0.5 μm, more preferably 0.005 to 0.2 μm, and still more preferably 0.01 to 0.1 μm. Within this range, the thickness which allows barrier properties and/or mechanical physical properties of the multilayer structure to become favorable may be selected. When the thickness of the inorganic vapor deposition layer (X′) is 0.002 μm or more, barrier properties against oxygen and/or water vapor of the inorganic vapor deposition layer (X′) tend to be favorable. Moreover, when the thickness of the inorganic vapor deposition layer (X′) is 0.5 μm or less, barrier properties after flexion of the inorganic vapor deposition layer (X′) tend to be maintained.

The thickness of the base (X) is 5 μm or more and 100 μm or less, and is preferably 7 μm or more and 80 μm or less, and more preferably 10 μm or more and 60 μm or less. When the thickness of the layer (X) is less than 5 μm, mechanical strength and processibility and peel strength tend to be deteriorated. Furthermore, when the thickness of the layer (X) exceeds 100 μm, flexibility of the multilayer structure to be obtained tends to be deteriorated.

As the base (X), one type of the base may be used alone, or two or more types of bases may be used in a combination. In the case in which multiple layers of the bases (X) are included, the bases (X) may each be the same or different. In the case in which a plurality of bases (X) are included, the thickness of the base (X) represents a thickness of each layer of the base (X). In light of flexibility and the like of the multilayer structure, including only one layer of the base (X) may be preferred.

Layer (Y)

The layer (Y) contains the reaction product (D) between the metal oxide (A) and the inorganic phosphorus compound (BI). Since, in the multilayer structure of the present invention, the layers (Y) function as barrier layers, the multilayer structure of the present invention tends to be prominently superior in the water vapor barrier properties due to including at least two layers (Y), the layers (Y) being provided on both faces of the base (X). The number of the layers (Y) in the multilayer structure of the present invention is not particularly limited as long as there are two or more, but in light of making flexibility of the multilayer structure of the present invention favorable, the number is preferably five or less, more preferably four or less, still more preferably three or less, and may be particularly preferably two. On the other hand, in intended usage for which more superior barrier properties are desired, increasing the number of the layers (Y) may be preferred. The two or more layers (Y) may be identical to or different from each other.

Metal Oxide (A) Containing Aluminum Atom

The metal atom (M) constituting the metal oxide (A) is, typically, at least one type of metal atom selected from metal atoms belonging to groups 2 to 14 in the periodic table, but includes at least an aluminum atom. The metal atom (M) is preferably an aluminum atom alone, but may include an aluminum atom and another metal atom. It is to be noted that as the metal oxide (A), two or more types of metal oxides (A) may be used after being mixed. Examples of the metal atom other than the aluminum atom include atoms of: metals belonging to group 2 in the periodic table such as magnesium and calcium; metals belonging to group 12 in the periodic table such as zinc; metals belonging to group 13 in the periodic table; metals belonging to group 14 in the periodic table such as silicon; transition metals such as titanium and zirconium; and the like. It is to be noted that although silicon is occasionally classified into metalloids, silicon is herein defined to be included into metals. The metal atom (M) which can be used in combination with aluminum is, in light of superior handleability and/or superior gas barrier properties of the multilayer structure to be obtained, preferably at least one selected from the group consisting of titanium and zirconium.

A proportion accounted for by an aluminum atom in the metal atom (M) is preferably 50 mol % or more, more preferably 70 mol % or more, and still more preferably 90 mol % or more, or may be 95 mol % or more. It is acceptable that the metal atom (M) substantially consists of an aluminum atom alone. Examples of the metal oxide (A) include metal oxides produced by a procedure such as liquid-phase synthesis, gas-phase synthesis, or solid grinding.

The metal oxide (A) may be a hydrolytic condensation product of a compound (E) (hereinafter, may be abbreviated to “compound (E)”) containing the metal atom (M) to which a characteristic group, being hydrolyzable, bonds. Examples of the characteristic group include: a halogen atom; NO3-; alkoxy groups, which may have a substituent, having 1 to 9 carbon atoms; aryloxy groups, which may have a substituent, having 6 to 9 carbon atoms; acyloxy groups, which may have a substituent, having 2 to 9 carbon atoms; alkenyloxy groups, which may have a substituent, having 3 to 9 carbon atoms; β-diketonato groups, which may have a substituent, having 5 to 15 carbon atoms; diacylmethyl groups having acyl groups, which may have a substituent, having 1 to 9 carbon atoms; and the like. The hydrolytic condensation product of the compound (E) can be substantially regarded as the metal oxide (A). Thus, the hydrolytic condensation product of the compound (E) may be herein referred to as the “metal oxide (A)”. In other words, as referred to herein, the “metal oxide (A)” may be construed as the “hydrolytic condensation product of the compound (E)”, and the “hydrolytic condensation product of the compound (E)” may be construed as the “metal oxide (A)”.

Compound (E) Containing Metal Atom (M) to which Characteristic Group, being Hydrolyzable, Bonds

It is preferred that the compound (E) includes a compound (Ea) containing an aluminum atom, described later, since controlling a reaction with the inorganic phosphorus compound (BI) may be facilitated, and the gas barrier properties of the multilayer structure to be obtained may be superior.

Examples of the compound (Ea) include aluminum chloride, aluminum nitrate, aluminum acetate, tris(2,4-pentanedionato)aluminum, trimethoxy aluminum, triethoxyaluminum, tri-n-propoxy aluminum, triisopropoxyaluminum, tri-n-butoxyaluminum, tri-sec-butoxyaluminum, tri-tert-butoxyaluminum, and the like, and of these, triisopropoxyaluminum and tri-sec-butoxyaluminum are preferred. As the compound (E), two or more types of the compound (Ea) may be used in combination.

In addition, the compound (E) may include a compound (Eb) containing the metal atom (M) other than aluminum, and examples of the compound (Eb) include: titanium compounds such as tetrakis(2,4-pentanedionato)titanium, tetramethoxytitanium, tetraethoxytitanium, tetraisopropoxytitanium, tetra-n-butoxytitanium, and tetrakis(2-ethylhexoxy)titanium; zirconium compounds such as tetrakis(2,4-pentanedionato)zirconium, tetra-n-propoxyzirconium, and tetra-n-butoxyzirconium; and the like. These may be used alone of one type, or in a combination of two or more types of the compound (Eb).

A proportion accounted for by the compound (Ea) in the compound (E) is not particularly limited, and is, for example, preferably 80 mol % or more, more preferably 90 mol % or more, and still more preferably 95 mol % or more, or may be 100 mol %.

Hydrolysis of the compound (E) results in conversion into a hydroxyl group from at least a part of the characteristic group, being hydrolyzable, included in the compound (E). Furthermore, condensation of the hydrolysate leads to formation of a compound to which the metal atom (M) is bonded via an oxygen atom (O). Repetition of this condensation results in formation of a compound which may be regarded substantially as a metal oxide. It is to be noted that a hydroxyl group is typically present on a surface of the metal oxide (A) thus formed.

As referred to herein, the metal oxide (A) involves a compound having a ratio [number of moles of the oxygen atom (O) bonding only to the metal atom (M)]/[number of moles of the metal atom (M)] being 0.8 or more. Here, the oxygen atom (O) bonding only to the metal atom (M) is an oxygen atom (O) in the structure represented by M-O-M, and an oxygen atom bonding to the metal atom (M) and a hydrogen atom (H), like the oxygen atom (O) in the structure represented by M-O-H, is excluded. The ratio in the metal oxide (A) is preferably 0.9 or more, more preferably 1.0, and still more preferably 1.1 or more. The upper limit of this ratio is not particularly limited, but provided that the atomic valence of the metal atom (M) is n, the upper limit is typically represented by n/2.

In order for the hydrolytic condensation to occur, it is important that the compound (E) has the characteristic group, which is hydrolyzable. In a case in which these groups are not bonded, the hydrolytic condensation reaction does not occur or is extremely slowed, whereby preparation of the metal oxide (A) intended may become difficult.

The hydrolytic condensation product of the compound (E) may be produced, for example, by a procedure adopted for a well-known sol-gel method, from a certain source material. The source material which can be used is at least one selected from the group consisting of: the compound (E); a partial hydrolysate of the compound (E); a complete hydrolysate of the compound (E); a compound produced by partial hydrolytic condensation of the compound (E); and a compound produced by partial condensation of a complete hydrolysate of the compound (E).

It is to be noted that the metal oxide (A) subjected to mixing with an inorganic phosphorus compound (BI)-containing material (the inorganic phosphorus compound (BI) or a composition containing the inorganic phosphorus compound (BI)), described later, preferably does not substantially contain a phosphorus atom.

Inorganic Phosphorus Compound (BI)

The inorganic phosphorus compound (BI) has a site which is capable of reacting with the metal oxide (A), typically has such a site in a plural number, and suitably has 2 to 20 such sites. The site includes a site capable of executing condensation reaction with a functional group (for example, a hydroxyl group) present on the surface of the metal oxide (A), and is exemplified by, for example, a halogen atom directly bonding to the phosphorus atom, an oxygen atom directly bonding to the phosphorus atom, and the like. The functional group (for example, a hydroxyl group) present on the surface of the metal oxide (A) typically bonds to the metal atom (M) constituting the metal oxide (A).

Examples of the inorganic phosphorus compound (BI) include: oxoacids of phosphorus such as phosphoric acid, diphosphoric acid, triphosphoric acid, polyphosphoric acid produced by condensation of 4 or more molecules of phosphoric acid, phosphorous acid, phosphonic acid, phosphonous acid, phosphinic acid, and phosphinous acid; salts of these (e.g., sodium phosphate); derivatives of the same (for example, halides (e.g., phosphoryl chloride) and dehydrates (e.g., diphosphorus pentoxide)); and the like. These may be used either alone of one type, or two or more types thereof may be used in combination. Of these, in light of improvements of: the gas barrier properties of the multilayer structure to be obtained; and stability of the coating liquid (S) described later, using phosphoric acid alone, or using phosphoric acid and an other inorganic phosphorus compound (BI) in a combination is preferred. In the case in which phosphoric acid and the other inorganic phosphorus compound (BI) are used in a combination, 50 mol % or more of the inorganic phosphorus compound (BI) is preferably phosphoric acid.

Reaction Product (D)

The reaction product (D) is obtained by a reaction between the metal oxide (A) and the inorganic phosphorus compound (BI). A compound produced by a reaction between the metal oxide (A) and the inorganic phosphorus compound (BI) and still another compound is also included in the reaction product (D).

In an infrared absorption spectrum of the layer (Y), it is preferred that a maximum absorption wavenumber in a region of 800 to 1,400 cm⁻¹ falls within the range of 1,080 to 1,130 cm⁻¹. For example, in the step of the reaction between the metal oxide (A) and the inorganic phosphorus compound (BI) to give the reaction product (D), a bond represented by M-O-P is formed via the oxygen atom (O) by: the metal atom (M) derived from the metal oxide (A); and a phosphorus atom (P) derived from the inorganic phosphorus compound (BI). As a result, a characteristic absorption band derived from the bond is generated in the infrared absorption spectrum of the reaction product (D). In the case in which the characteristic absorption band resulting from the bond of M-O-P is found in the region of 1,080 to 1,130 cm⁻¹, the multilayer structure to be obtained may have superior gas barrier properties. Particularly, in a case in which the characteristic absorption band exhibits the strongest absorption in the region of 800 to 1,400 cm⁻¹ in which absorptions derived from bonds between various types of atoms and an oxygen atom are found in general, the multilayer structure to be obtained may be superior in gas barrier properties. In other words, the multilayer structure of the present invention has a moisture permeability measured in accordance with ISO15106-5 being more likely to be readily adjusted to 1.0×10⁻² g/m²·day or less when, in the infrared absorption spectrum of the layer (Y), the maximum absorption wavenumber in the region of 800 to 1,400 cm⁻¹ falls within the range of 1,080 to 1,130 cm⁻¹.

In contrast, in a case in which hydrolytic condensation is allowed after the inorganic phosphorus compound (BI) and a metal compound such as the compound (E) or a metal salt are mixed beforehand, a complex is obtained in which the metal atom derived from the metal compound is reacted with the phosphorus atom derived from the inorganic phosphorus compound (BI) through admixing in a nearly homogenous manner. In this case, in the infrared absorption spectrum, the maximum absorption wavenumber in the region of 800 to 1,400 cm⁻¹ will deviate from the range of 1,080 to 1,130 cm⁻¹.

In the infrared absorption spectrum of the layer (Y), a full width half maximum of the maximum absorption band in the region of 800 to 1,400 cm⁻¹ is, in light of the gas barrier properties of the multilayer structure to be obtained, preferably 200 cm⁻¹ or less, more preferably 150 cm⁻¹ or less, still more preferably 100 cm⁻¹ or less, and particularly preferably 50 cm⁻¹ or less.

The infrared absorption spectrum of the layer (Y) can be determined according to attenuated total reflection by using a Fourier transform infrared spectrophotometer (Spectrum One, manufactured by PerkinElmer, Inc.) with a region for determination of 800 to 1,400 cm⁻¹. However, in a case of failure of determination by the procedure described above, determination may be carried out according to a procedure, e.g.: reflection measurement such as reflection absorption, external reflection, or attenuated total reflection; or scraping the layer (Y) from the multilayer structure, followed by transmission measurement by a Nujol mull technique or a tablet technique, but is not limited thereto.

Also, the layer (Y) may partially contain the metal oxide (A) and/or the inorganic phosphorus compound (BI) which are/is not involved in the reaction.

In the layer (Y), with respect to a molar ratio of the metal atom (M) constituting the metal oxide (A) to the phosphorus atom derived from the inorganic phosphorus compound (BI), the ratio [metal atom (M) constituting the metal oxide (A)]:[phosphorus atom derived from the inorganic phosphorus compound (BI)] preferably falls within the range of 1.0:1.0 to 3.6:1.0, and more preferably falls within the range of 1.1:1.0 to 3.0:1.0. Within this range, superior gas barrier performance may be achieved. This molar ratio in the layer (Y) can be adjusted by a mixing proportion of the metal oxide (A) and the inorganic phosphorus compound (BI) in the coating liquid (S) for forming the layer (Y), as described later. This molar ratio in the layer (Y) is typically the same as the ratio in the coating liquid (S) described later.

The layer (Y) may contain at least one selected from the group consisting of an organic phosphorus compound (BO) and a polymer (F). Due to containing at least one selected from the group consisting of the organic phosphorus compound (BO) and the polymer (F), the layer (Y) may tend to be capable of maintaining favorable gas barrier properties even after subjecting the multilayer structure of the present invention to flexion. Hereinafter, the property of being capable of maintaining the gas barrier properties even after being subjected to flexion may be referred to as “flex resistance”.

Organic Phosphorus Compound (BO)

The organic phosphorus compound (BO) is preferably a polymer (BOa) having a plurality of phosphorus atoms, or an organic phosphorus compound (Bob).

Polymer (BOa) Having a Plurality of Phosphorus Atoms

A phosphorus atom-containing functional group included in the polymer (BOa) is exemplified by a phosphoric acid group, a phosphorous acid group, a phosphonic acid group, a phosphonous acid group, a phosphinic acid group, a phosphinous acid group, and a functional group derived therefrom (for example, a salt, a (partial) ester compound, a halide (e.g., chloride), a dehydrate), and the like. Of these, a phosphoric acid group and a phosphonic acid group are preferred, and a phosphonic acid group is more preferred.

Examples of the polymer (BOa) include: polymers of phosphono(meth)acrylic acid esters such as 6-[(2-phosphonoacetyl)oxy]hexyl acrylate, 2-phosphonooxyethyl methacrylate, phosphonomethyl methacrylate, 11-phosphonoundecyl methacrylate, and 1,1-diphosphonoethyl methacrylate; polymers of vinylphosphonic acids such as vinylphosphonic acid, 2-propene-1-phosphonic acid, 4-vinylbenzylphosphonic acid, and 4-vinylphenylphosphonic acid; polymers of vinylphosphinic acids such as vinylphosphinic acid and 4-vinylbenzylphosphinic acid; phosphorylated starch; and the like. The polymer (BOa) may be a homopolymer of a monomer having a functional group containing at least one phosphorus atom, or may be a copolymer of two or more types of monomers. Also, as the polymer (BOa), two or more types of polymers each formed from a single monomer may be used in a combination. Of these, polymers of phosphono(meth)acrylic acid esters and polymers of vinylphosphonic acids are preferred, polymers of vinylphosphonic acids are more preferred, and polyvinylphosphonic acid is still more preferred. Also, the polymer (BOa) can be obtained by homopolymerizing or copolymerizing a vinylphosphonic acid derivative such as a vinylphosphonic halide or a vinylphosphonic acid ester, followed by allowing for hydrolysis.

Alternatively, the polymer (BOa) may be a copolymer of a monomer having a functional group containing at least one phosphorus atom, and an other vinyl monomer. Examples of the other vinyl monomer which is copolymerizable with a monomer having a functional group containing a phosphorus atom include (meth)acrylic acid, (meth)acrylic acid esters, acrylonitrile, methacrylonitrile, styrene, nuclear substituted styrenes, alkyl vinyl ethers, alkylvinyl esters, perfluoroalkyl vinyl ethers, perfluoroalkylvinyl esters, maleic acid, maleic anhydride, fumaric acid, itaconic acid, maleimide, phenylmaleimide, and the like. Of these, (meth)acrylic acid esters, acrylonitrile, styrene, maleimide, and phenylmaleimide are preferred.

In order to obtain the multilayer structure having superior flex resistance, a proportion of total constitutional units of the polymer (BOa) accounted for by a constitutional unit derived from the monomer having a functional group containing a phosphorus atom is preferably 10 mol % or more, more preferably 40 mol % or more, still more preferably 70 mol % or more, and particularly preferably 90 mol % or more, or may be 100 mol %.

Although a molecular weight of the polymer (BOa) is not particularly limited, the number average molecular weight preferably falls within the range of 1,000 to 100,000. When the number average molecular weight falls within this range, an effect of improving the flex resistance of the multilayer structure of the present invention, and viscosity stability of the coating liquid (S), described later, in use of the coating liquid (S) may be both achieved at high levels.

In the case in which the polymer (BOa) is contained in the layer (Y) of the multilayer structure, a ratio, W_{BOa}/W_{BI}, W_{BI} being a mass of the inorganic phosphorus compound (BI) to W_{BOa} being a mass of the polymer (BOa), in the layer (Y) preferably satisfies a relationship of 0.01/99.99≤W_{BOa}/W_{BI}<6.00/94.00, and in light of superior barrier performance, the ratio W_{BOa}/W_{BI} more preferably satisfies a relationship of 0.10/99.90≤W_{BOa}/W_{BI}<4.50/95.50, still more preferably satisfied a relationship of 0.20/99.80≤W_{BOa}/W_{BI}<4.00/96.00, and particularly preferably satisfies a relationship of 0.50/99.50≤W_{BOa}/W_{BI}<3.50/96.50. In other words, it is preferred that WBo a being as small as 0.01 or more and less than 6.00 indicating a small amount, whereas W_{BI}being more than 94.00 and 99.99 or less indicating a large amount employed. It is to be noted that even in a case in which the inorganic phosphorus compound (BI) and/or the organic phosphorus compound (BOa) react in the layer (Y), part(s) of the inorganic phosphorus compound (BI) and/or the organic phosphorus compound (BOa) constituting the reaction product (D) is/are regarded as the inorganic phosphorus compound (BI) and/or the organic phosphorus compound (BOa). In this case, a mass of the inorganic phosphorus compound (BI) and/or the organic phosphorus compound (BOa) used for forming the reaction product (D) (a mass of the inorganic phosphorus compound (BI) and/or the organic phosphorus compound (BOa) before the reaction) is included in the mass of the inorganic phosphorus compound (BI) and/or the organic phosphorus compound (BOa) in the layer (Y).

Organic Phosphorus Compound (BOb)

In the organic phosphorus compound (BOb), via an alkylene chain having 3 or more and 20 or fewer carbon atoms or a polyoxyalkylene chain having 3 or more and 20 or fewer carbon atoms, a polar group bonds to a phosphorus atom to which at least one hydroxyl group bonds. The organic phosphorus compound (BOb) has lower surface free energy as compared with the metal oxide (A), the inorganic phosphorus compound (BI), and their reaction product (D), and thus organic phosphorus compound (BOb) segregated on a front face side in the step of forming a precursor of the layer (Y). As a result, flex resistance, and adhesiveness to layers when directly laminated to the layer (Y) of the multilayer structure of the present invention may be improved.

Specific examples of the organic phosphorus compound (BOb) include 3-hydroxypropylphosphonic acid, 4-hydroxybutylphosphonic acid, 5-hydroxypentylphosphonic acid, 6-hydroxyhexylphosphonic acid, 7-hydroxyheptylphosphonic acid, 8-hydroxyoctylphosphonic acid, 9-hydroxynonylphosphonic acid, 10-hydroxydecylphosphonic acid, 11-hydroxyundecylphosphonic acid, 12-hydroxydodecylphosphonic acid, 13-hydroxidetridecylphosphonic acid, 14-hydroxytetradecylphosphonic acid, 15-hydroxypentadecylphosphonic acid, 16-hydroxyhexadecylphosphonic acid, 17-hydroxyheptadecylphosphonic acid, 18-hydroxyoctadecylphosphonic acid, 19-hydroxynonadecylphosphonic acid, 20-hydroxyicosylphosphonic acid, 3-hydroxypropyldihydrogenphosphate, 4-hydroxybutyldihydrogenphosphate, 5-hydroxypentyldihydrogenphosphate, 6-hydroxyhexyldihydrogenphosphate, 7-hydroxyheptyldihydrogenphosphate, 8-hydroxyoctyldihydrogenphosphate, 9-hydroxynonyldihydrogenphosphate, 10-hydroxydecyldihydrogenphosphate, 11-hydroxyundecyldihydrogenphosphate, 12-hydroxydodecyldihydrogenphosphate, 13-hydroxidetridecyldihydrogenphosphate, 14-hydroxytetradecyldihydrogenphosphate, 15-hydroxypentadecyldihydrogenphosphate, 16-hydroxyhexadecyldihydrogenphosphate, 17-hydroxyheptadecyldihydrogenphosphate, 18-hydroxyoctadecyldihydrogenphosphate, 19-hydroxynonadecyldihydrogenphosphate, 20-hydroxyicosyldihydrogenphosphate, 3-carboxypropylphosphonic acid, 4-carboxybutylphosphonic acid, 5-carboxypentylphosphonic acid, 6-carboxyhexylphosphonic acid, 7-carboxyheptylphosphonic acid, 8-carboxyoctylphosphonic acid, 9-carboxynonylphosphonic acid, 10-carboxydecylphosphonic acid, 11-carboxyundecylphosphonic acid, 12-carboxydodecylphosphonic acid, 13-carboxidetridecylphosphonic acid, 14-carboxytetradecylphosphonic acid, 15-carboxypentadecylphosphonic acid, 16-carboxyhexadecylphosphonic acid, 17-carboxyheptadecylphosphonic acid, 18-carboxyoctadecylphosphonic acid, 19-carboxynonadecylphosphonic acid, 20-carboxyicosylphosphonic acid, and the like. One type of these may be used alone, or two or more types thereof may be used in combination.

In the case in which the organic phosphorus compound (BOb) is contained in the layer (Y) of the multilayer structure, a ratio M_{BOb}/M_{BI}, M_{BOb} being the number of moles of the organic phosphorus compound (BOb) to M_{BI} being the number of moles of the inorganic phosphorus compound (BI), in the layer (Y) preferably satisfies a relationship of 1.0×10⁻⁴≤M_{BOb}/M_{BI}≤2.0×10⁻², more preferably satisfies a relationship of 3.5×10⁻⁴≤M_{BOb}/M_{BI}≤1.0×10⁻², and still more preferably satisfies a relationship of 5.0×10⁻⁴≤M_{BOb}/M_{BI}≤6.0×10⁻³.

In the case in which the layer (Y) contains the organic phosphorus compound (BOb), a C/Al ratio of the layer (Y) from the surface to 5 nm on a side not being in contact with the base (X) of the multilayer structure, as measured by X-ray photoelectron pectroscopy (XPS), preferably falls within the range of 0.1 to 15.0, more preferably falls within the range of 0.3 to 10.0, and particularly preferably falls within the range of 0.5 to 5.0. When the C/Al ratio of the surface of the layer (Y) falls within the above range, adhesiveness to any layer adjacent to the layer (Y) may be improved.

A total thickness of layers (Y) is preferably 0.05 to 4.0 μm, and more preferably 0.1 to 2.0 μm. Thinning of the layer (Y) may enable minimizing dimensional alteration of the multilayer structure during processing thereof such as printing and laminating. In addition, due to an increase in flexibility of the multilayer structure, dynamic characteristics of the same can be approximate to dynamic characteristics of the base per se. Due to including two or more layers (Y) in the multilayer structure of the present invention, in light of the gas barrier properties, the thickness of each layer of the layers (Y) is preferably 0.05 μm or more, and in light of the flex resistance, the thickness is preferably 1.0 μm or less. The thickness of each layer of the layers (Y) can be controlled by a concentration of the coating liquid (S) for use in forming the layer (Y) as described later, or by a procedure of applying the same. The thickness of the layer (Y) can be measured by inspection of the cross section of the multilayer structure, with a scanning electron microscope or a transmission electron microscope.

Polymer (F)

The layer (Y) may contain the polymer (F) having at least one type of functional group selected from the group consisting of a carbonyl group, a hydroxyl group, a carboxy group, a carboxylic anhydride group, and a salt of a carboxyl group. The polymer (F) is preferably a polymer having at least one type of functional group selected from the group consisting of a hydroxyl group and a carboxyl group. When the layer (Y) contains the polymer (F), flex resistance may be favorable.

Examples of the polymer (F) include: polyethylene glycol; polyvinyl alcohol polymers such as a polyvinyl alcohol, a modified polyvinyl alcohol containing 1 to 50 mol % α-olefin unit having 4 or fewer carbon atoms, and polyvinyl acetal (polyvinylbutyral, etc.); polysaccharides such as cellulose and starch; (meth)acrylic acid polymers such as polyhydroxyethyl (meth)acrylate, poly(meth)acrylic acid, and an ethylene-acrylate copolymer; maleic acid polymers such as a hydrolysate of an ethylene-maleic anhydride copolymer, a hydrolysate of a styrene-maleic anhydride copolymer, and a hydrolysate of an isobutylene-maleic anhydride alternating copolymer; and the like. Of these, polyethylene glycol or the polyvinyl alcohol polymer is preferred.

The polymer (F) may be: a homopolymer of a monomer having a polymerizable group; or a copolymer of two or more types of monomers, or may be a copolymer of a monomer having at least one type of functional group selected from the group consisting of a carbonyl group, a hydroxyl group, a carboxyl group, a carboxylic anhydride group, and a salt of a carboxyl group, with a monomer not having any of these groups. It is to be noted that as the polymer (F), a mixture of two or more types of the polymer (F) may be used.

The molecular weight of the polymer (F) is not particularly limited, and in order to obtain the multilayer structure having much superior gas barrier properties and mechanical strength, the weight average molecular weight of the polymer (F) is preferably 5,000 or more, more preferably 8,000 or more, and still more preferably 10,000 or more. The upper limit of the weight average molecular weight of the polymer (F) is not particularly limited, and is, for example, 1,500,000.

In light of the appearance of the multilayer structure being maintained favorably, a content of the polymer (F) in the layer (Y), on the basis of the mass of the layer (Y), is preferably less than 50% by mass, more preferably 20% by mass or less, still more preferably 10% by mass or less, and may also be 5% by mass or less or 2% by mass or less, or may be 0% by mass. The polymer (F) may have or may not have reacted with components in the layer (Y).

The layer (Y) may further contain other component(s). Examples of the other component which may be contained in the layer (Y) include: inorganic acid metal salts such as a carbonate, a hydrochloride, a nitrate, a hydrogencarbonate, a sulfate, a hydrogensulfate, and a borate; organic acid metal salts such as an oxalate, an acetate, a tartarate, and a stearate; metal complexes such as a cyclopentadienyl metal complex (for example, titanocene) and a cyano metal complex (for example, Prussian blue); layered clay compounds; crosslinking agents; polymer compounds other than the polymer (BOa) and the polymer (F); plasticizers; antioxidants; ultraviolet ray-absorbing agent; fire retardants; and the like. A percentage content of the other component(s) in the layer (Y) in the multilayer structure is preferably 20% by mass or less, more preferably 10% by mass or less, and still more preferably 5% by mass or less, or may be 3% by mass or less, 1% by mass or less, or 0% by mass (with the other component(s) not being contained).

The laminate constituting the multilayer structure of the present invention may be provided with a layer (W) which contains at least one selected from the group consisting of the organic phosphorus compound (BO) and the polymer (F), being directly laminated on a face of the layer (Y) on an opposite side to the base (X). Due to being provided with the layer (W), it may be possible to improve the flex resistance, and/or to enhance adhesiveness to an adhesive layer (I), described later. In addition, the laminate constituting the multilayer structure of the present invention may be provided with an adhesive layer (AC) between the base (X) and the layer (Y). Due to being provided with the adhesive layer (AC), adhesiveness between the base (X) and the layer (Y) may be enhanced.

Layer (W)

In the case in which the laminate includes the layer (W), it is preferred that the layer (W) is directly laminated with the layer (Y). Suitable modes of the organic phosphorus compound (BO) and the polymer (F) which may be contained in the layer (W) are as described above.

The layer (W) may further contain other component(s). Examples of the other component include: inorganic acid metal salts such as a carbonate, a hydrochloride, a nitrate, a hydrogencarbonate, a sulfate, a hydrogensulfate, and a borate; organic acid metal salts such as an oxalate, an acetate, a tartarate, and a stearate; metal complexes such as a cyclopentadienyl metal complex (for example, titanocene) and a cyano metal complex (for example, Prussian blue); layered clay compounds; crosslinking agents; polymer compounds other than the polymer (BOa) and the polymer (F); plasticizers; antioxidants; ultraviolet ray-absorbing agent; fire retardants; and the like. A percentage content of the other component(s) in the layer (W) is preferably 20% by mass or less, more preferably 10% by mass or less, and still more preferably 5% by mass or less, or may be 2% by mass or less, 1% by mass or less, or 0% by mass (with the other component(s) not being contained).

In the case in which the laminate is provided with the layer (W), the thickness thereof is, in light of the flex resistance of the multilayer structure of the present invention being more favorable, preferably 0.005 μm or more. The upper limit of the thickness of the layer (W) is not particularly limited, but the upper limit of the thickness of the layer (W) being 1.0 μm is economically preferred since the effect of improving the flex resistance reaches saturation when the thickness is 1.0 μm or more.

Adhesive Layer AC

An adhesive constituting the adhesive layer (AC) is not particularly limited as long as it has adhesiveness between the base (X) and the layer (Y), and is exemplified by a polyurethane-based adhesive, a polyester-based adhesive, and the like. It may be possible to further enhance the adhesiveness by adding a small amount of additive(s) such as a well-known silane coupling agent, to any of these adhesives. The silane coupling agent is exemplified by silane coupling agents each having a reactive group such as an isocyanate group, an epoxy group, an amino group, a ureide group, or a mercapto group.

As the polyurethane-based adhesive, a well-known one may be used, and a two-component polyurethane-based adhesive is preferably used provided by mixing a polyisocyanate component and a polyol component to allow for a reaction. As the two-component polyurethane-based adhesive, a commercially available product may be used, and TAKELAC (registered trademark) and TAKENATE (registered trademark), each manufactured by Mitsui Chemicals, Inc., and the like may be exemplified.

As the polyester-based adhesive, a well-known one may be used, and examples of commercially available products include elitel (registered trademark) KT-0507, KT-8701, KT-8803, KT-9204, KA-5034, KA-3556, KA-1449, KA-5071S, and KZA-1449S, (each manufactured by Unitika Limited), VYLONAL (registered trademark) MD-1200 and VYLONAL MD-1480 (each manufactured by Toyobo Co., Ltd.), PESRESIN A124GP and PESRESIN A684G (manufactured by Takamatsu Oil & Fat Co., Ltd.), and the like. By adding a vinyl alcohol resin, particularly polyvinyl alcohol to the polyester-based adhesive, the adhesiveness may be more enhanced. In the case in which the vinyl alcohol resin and the polyester resin are used concomitantly, a mass ratio thereof (the vinyl alcohol resin/the polyester resin) is preferably 1/99 or more and 50/50 or less, in light of higher peel strength being exhibited while favorable adhesiveness is maintained. The polyester resin is, in light of affinity with the vinyl alcohol resin, preferably a polyester resin having a carboxyl group. In addition, when used as the adhesive, the polyester resin is preferably in an aqueous dispersion form. Due to the polyester resin being in the form of an aqueous dispersion, affinity with the polyvinyl alcohol resin tends to be more favorable. The thickness of the adhesive layer (AC) is preferably 0.001 to 10.0 μm, and more preferably 0.01 to 5.0 μm.

Laminate

The laminate constituting the multilayer structure of the present invention includes the base (X) and at least two layers (Y), the layers (Y) being provided on both faces of the base (X). Although the layers (Y) may be directly laminated on the base (X) or may be laminated via an other layer as long as the layers (Y) are provided on both faces of the base (X), it is preferred that the layers (Y) are directly laminated on both faces of the base (X), or the layers (Y) are laminated via the adhesive layer (AC) on both faces of the base (X), in light of favorable achievement of the peel strength with respect to the sealant of the multilayer structure of the present invention. Furthermore, the laminate may include the layer (W) directly laminated on an exposed surface side of the layer (Y). When the layer (W) is provided on the exposed surface side of the layer (Y), it may be possible to improve the flex resistance of the multilayer structure of the present invention, and/or to enhance adhesiveness to the adhesive layer (I) described later.

Specific examples of the laminate are shown below; however, a plurality of the specific examples may be combined into a configuration, e.g., a configuration in which the configurations of (1) are laminated via the adhesive layer (I) (layer (Y)//base (X)//layer (Y)/adhesive layer (I)/layer (Y)//base (X)//layer (Y)), or each layer may be provided in a plural number. As referred to herein, “/” means “being directly laminated”, and “//” means “being directly laminated, or being laminated via the adhesive layer (AC)”.
(1) layer (Y)//base (X)//layer (Y)
(2) layer (W)/layer (Y)//base (X)//layer (Y)/layer (W)
(3) layer (Y)//base (X)//layer (Y)//base (X)//layer (Y)

The laminate tends to have, when heated at 160° C. for 30 min, a small thermal shrinkage percentage TS in the MD direction. Although the reasons for this phenomenon are not clarified, the following two reasons have been presumed: (1) because of the layer (Y) being provided, the layer (Y) having a lower thermal shrinkage percentage as compared with thermoplastic resins and the like; and (2) because of a decrease in thermal shrinkage percentage of the laminate to be obtained, since thermal shrinkage occurs due to a heat treatment at a high temperature in producing the laminate, as explained with respect to a production method described below. The thermal shrinkage percentage TS in an MD direction of the laminate when heated at 160° C. for 30 min is preferably 1.0% or less, more preferably 0.70% or less, still more preferably 0.50% or less, and particularly preferably 0.40% or less. When the thermal shrinkage percentage TS is 1.0% or less, enhancing peel strength, particularly the peel strength after a wet heat treatment, of the multilayer structure of the present invention tends to be enabled. In addition, when the base (X) is thin, the thermal shrinkage percentage TS tends to increase. The thermal shrinkage percentage TS may be or more.

Layer (Z)

The multilayer structure of the present invention includes layers (Z) containing a thermoplastic resin as a principal component and being laminated via each of adhesive layers (I) on both faces of the laminate, and the layers (Z) provided on the both faces may be identical to or different from each other. Herein, “containing a thermoplastic resin as a principal component” as referred to means that a proportion accounted for by the thermoplastic resin in the layer (Z) exceeds 50% by mass. The multilayer structure of the present invention can, due to the layers (Z) being provided, have enhanced peel strength with respect to the sealant, and further, due to the thickness of the layers (Z) being 5 μm or more and 100 μm or less, improving the flexibility of the multilayer structure of the present invention is enabled. The thermoplastic resin constituting the layer (Z) is not particularly limited, and a thermoplastic resin having superior peel strength with respect to the sealant is preferably used for the layer (Z). The thermoplastic resin having superior peel strength with respect to the sealant is not particularly limited since the peel strength may vary depending on the type of the sealant, and examples of the thermoplastic resin include: polyolefin resins such as polyethylene, polypropylene, and cyclic olefin copolymers; polyester resins such as polyethylene terephthalate (PET), polyethylene naphthalate, polybutylene terephthalate, and copolymers of the same; polyamide resins such as nylon-6, nylon-66, and nylon-12; hydroxyl group-containing polymers such as polyvinyl alcohol and ethylene-vinyl alcohol copolymers; polystyrene; poly(meth)acrylic acid esters; polyacrylonitrile; polyvinyl acetate; polycarbonate; polyarylate; regenerated cellulose; polyimide; polyetherimide; poly sulfone; polyethersulfone; polyether ether ketone; ionomer resins; and the like. In light of transparency, the thermoplastic resin used for the layer (Z) is preferably at least one selected from the group consisting of polyethylene, polypropylene, polyethylene terephthalate, polyethylene naphthalate, polycarbonate, nylon-6, and nylon-66, and in light of enabling favorable peel strength to be achieved in the case in which the ethylene-vinyl acetate copolymer (EVA) is used as the sealant, polyethylene terephthalate is more preferred.

A proportion accounted for by the thermoplastic resin in the layer (Z) is more than 50% by mass, preferably 70% by mass or more, more preferably 90% by mass or more, and still more preferably 95% by mass or more, or the layer (Z) may be substantially constituted from only the thermoplastic resin, or the layer (Z) may be constituted from only the thermoplastic resin.

The layer (Z) preferably has a film shape. The layer (Z) may be either a stretched film or an unstretched film. In order for the multilayer structure to be obtained having superior processing suitability (for printing, laminating, etc.), a stretched film, in particular, a biaxially stretched film, is preferred. The biaxially stretched film may be a biaxially stretched film produced by any method of simultaneous biaxial stretching, sequential biaxial stretching, and tubular stretching.

The thickness of each layer of the layers (Z) is 5 μm or more, more preferably 7 μm or more, and still more preferably 10 μm or more. Further, the thickness of each layer of the layers (Z) is 100 μm or less, more preferably 80 μm or less, still more preferably 60 μm or less, and even more preferably 40 μm or less, or there may be a case in which 30 μm or less is preferred. When the thickness of each layer of the layers (Z) is less than 5 μm, mechanical strength, processibility, and peel strength of the multilayer structure to be obtained tends to be deteriorated. On the other hand, when the thickness of each layer of the layers (Z) exceeds 100 μm, the flexibility of the multilayer structure to be obtained tends to be deteriorated.

A thermal shrinkage percentage TS_{z} in the MD direction when heated at 160° C. for 30 min of the layer (Z), is preferably 0.50% or more, more preferably 0.80% or more, and still more preferably 0.90% or more. When TS_{z} is 0.50% or more, the adhesiveness of the sealant tends to be increased. Also, the thermal shrinkage percentage TS_{z} may be 4.0% or less, 3.0% or less, 2.0% or less, or 1.4% or less. It is to be noted that when the layer (Z) is thin, thermal shrinkage percentage TS_{z} tends to increase. In a case in which the thermal shrinkage percentage TS of the laminate forming the multilayer structure of the present invention is low, maintaining the peel strength of the multilayer structure of the present invention after the wet heat treatment tends to be enabled even when the thermal shrinkage percentage TS_{z} value is high.

Adhesive Layer (I)

The multilayer structure of the present invention includes the adhesive layers (I) each between the laminate and the layer (Z). The adhesive layers (I) provided on both faces of the laminate may be identical to or different from each other. Due to including the adhesive layers (I) each between the laminate and the layer (Z), the multilayer structure of the present invention can have increased adhesiveness between the laminate and the layers (Z), whereby the peel strength with respect to the sealant tends to be sufficiently achievable. The adhesive layer (I) is acceptable as long as it is transparent upon, e.g., curing with heat, etc. or curing with light, etc., and has potent adhesive force. For example, an adhesive which is capable of permitting adhesion by way of, e.g., curing with isocyanate, etc., curing with heat, etc., or curing with light, etc., as well as an agglutinant or the like may be used as the adhesive layer (I). An adhesive constituting the adhesive layer (I) is not particularly limited as long as it has adhesiveness between the laminate and the layer (Z), and a urethane-based adhesive, an ester-based adhesive, an acrylic adhesive, or the like may be used. Of these, the urethane-based adhesive is preferred, and a two-reactive component polyurethane-based adhesive provided by mixing a polyisocyanate component and a polyol component to allow for a reaction is more preferred.

The thickness of each layer of the adhesive layers (I) is preferably 0.5 μm to 20 μm, more preferably 0.5 μm to 15 μm, and still more preferably 1 μm to 10 μm. When the thickness of each layer of the adhesive layers (I) is 0.5 μm or more, the adhesiveness tends to improve, and when the thickness is 20 μm or less, flexibility of the multilayer structure to be obtained tends to be improved.

Easily Adhered Layer (EA)

The multilayer structure of the present invention includes, in light of enhancing the peel strength with respect to the sealant, the easily adhered layer (EA) preferably laminated on at least one exposed surface side of the layers (Z), and the easily adhered layer (EA) more preferably provided on exposed surface sides of both of the layers (Z). As referred to herein, the “easily adhered layer” means a layer that enhances the peel strength with respect to the sealant. The “exposed surface” of the layer (Z) as referred to herein means, with respect to the two faces of the layer (Z), a face on a side opposite to a face side where the laminate is placed, and is to be exposed in a case of the absence of the easily adhered layer provided. Due to the easily adhered layer (EA) being laminated, maintaining interlayer peel strength tends to be enabled even at a high temperature and under high humidity. For example, by using the multilayer structure of the present invention for a solar cell protective sheet, a solar cell module can be provided, which is accompanied by less lowering of the output even after exposure to an environment involving a high temperature and high humidity for a long time period.

The easily adhered layer (EA) is not particularly limited, and for example, an acrylic resin, a polyolefin resin, a polyester resin, a polyurethane resin, a polyamide resin, and/or a polyvinyl alcohol resin may be contained. Of these, containing at least one selected from the group consisting of the acrylic resin, the polyolefin resin, the polyester resin, and the polyurethane resin is preferred, and containing the acrylic resin is more preferred.

In one mode of a method for providing the easily adhered layer (EA), a method of production by applying an adhesive containing a crosslinkable base resin, a crosslinking agent, etc., and a solvent (containing an organic medium as a main solvent, or containing an aqueous medium as a main solvent) on the layer (Z), followed by drying is exemplified. As such an adhesive, a well-known one may be used, and examples of commercially available products include Dinareo (registered trademark) (manufactured by Toyochem Co., Ltd.), Arrowbase (registered trademark) SD-1200, SB-1200, and SE-1200 (all manufactured by Unitika Limited), PESRESIN A124GP and PESRESIN A684G (manufactured by Takamatsu Oil & Fat Co., Ltd.), and the like.

In the case in which the easily adhered layer (EA) contains the acrylic resin, a number average molecular weight of the acrylic resin is preferably 17,000 to 250,000. When the number average molecular weight falls within the above range, the peel strength with respect to the sealant, and wet and heat resistance tend to be favorable.

The easily adhered layer (EA) of the present invention may contain inorganic particles and/or organic particles. By containing these particles, adhesion durability may be improved. The inorganic particle is exemplified by a silicate or a carbonate of a metal. Specific examples include a silicate and a carbonate of a metal such as magnesium, aluminum, calcium, barium, zinc, iron, lithium, titanium, or the like. The organic particle which may be preferably used has a melting point or softening point of 150° C. or more. When the melting point or the softening point of the organic particle is lower than 150° C., the particle may be softened in a vacuum lamination step, whereby adhesion to the sealant may be hampered. Specific examples of the organic particle include polymer particles of a polymethyl methacrylate resin, a polystyrene resin, a nylon (registered trademark) resin, a melamine resin, a guanamine resin, a phenol resin, a urea resin, a silicon resin, a methacrylate resin, an acrylate resin or the like, and cellulose powder, nitrocellulose powder, wood powder, waste paper powder, rice husk powder, starch, and the like. One of the inorganic particle and the organic particle may be used, or two or more types thereof may be used in combination. In addition, the easily adhered layer (EA) may also contain, within a range not to inhibit the effects of the present invention, additive(s) capable of enhancing weather resistance (an antioxidant, an ultraviolet-ray stabilizer, a metal deactivator, etc.).

A thickness of each layer of the easily adhered layer (EA) is preferably 0.01 to 10 μm, more preferably 0.05 to 8 μm, and still more preferably 0.05 to 5 μm. When the thickness of each layer of the easily adhered layer (EA) falls within the above range, peel strength with respect to the sealant and flexibility of the multilayer structure to be obtained tend to be favorable.

In the case in which a plurality of easily adhered layers (EA) are provided, the easily adhered layers (EA) may be identical to or different from each other.

The multilayer structure of the present invention may also include an inorganic vapor deposition layer which is not arranged as the base (X). A suitable mode of the inorganic vapor deposition layer is similar to the suitable mode of the inorganic vapor deposition layer (X′) described above.

A thickness (total thickness of all layers) of the multilayer structure of the present invention is 15 μm or more, preferably 17 μm or more, still more preferably 20 μm or more, and particularly preferably 30 μm or more. In addition, the thickness of the multilayer structure of the present invention is 120 μm or less, preferably 110 μm or less, still more preferably 100 μm or less, and particularly preferably 90 μm or less. When the thickness is 15 μm or more, mechanical strength may be favorable, and processibility during production of the multilayer structure tends to be favorable. Moreover, when the thickness is 120 μm or less, flexibility of the multilayer structure tends to be favorable.

With respect to the thermal shrinkage percentage in the MD direction when heated at 160° C. for 30 min, a ratio (TS_{Z}/TS), of the thermal shrinkage percentage TS_{Z} of the layer (Z) to the thermal shrinkage percentage TS of the laminate is preferably 2 or more, more preferably 2.5 or more, and still more preferably 3.0 or more, or may be even more preferably 3.5 or more, 4.0 or more, or 4.5 or more. When the ratio (TS_{Z}/TS) is 2 or more, dimension accuracy and the peel strength with respect to the sealant of the multilayer structure tend to be favorable. Although the reason for this feature is not clarified, it is presumed that TS being low may result in favorable dimension accuracy of the multilayer structure, and high TS_{Z} may result in an improved anchoring effect at an interface of the sealant and the multilayer structure during shrinkage, whereby the peel strength may improve. The ratio (TS_{z}/TS) may be 20 or less, or 10 or less.

A moisture permeability of the multilayer structure of the present invention measured at 40° C. and 90% RH is 1.0×10^{31 2} g/m²·day or less, preferably 8.0 ×10⁻³ g/m²·day or less, and more preferably 5.0 ×10⁻³ g/m²·day or less. The moisture permeability can be measured in accordance with ISO15106-5:2015, with DELTAPERM manufactured by Technolox Ltd. The moisture permeability may be 1.0×10⁻⁵ g/m²·day or more, 1.0×10⁻⁴ g/m²·day or more, or may be 5.0×10⁻⁴ g/m²·day or more. Means for allowing the moisture permeability to be 1.0×10^{31 2} g/m²·day or less may be exemplified by: providing at least two layers (Y); adjusting the maximum absorption wavenumber in the region of 800 to 1,400 cm⁻¹ in an infrared absorption spectrum of the layer (Y) to fall within the range of 1,080 to 1,130 cm⁻¹; providing a layer having low moisture permeability; and the like.

It is preferred that the multilayer structure of the present invention is directly laminated with the sealant of an electronic device or the like, described later. The peel strength of the multilayer structure of the present invention before the wet heat treatment, as measured in the peel strength test described in EXAMPLES, is preferably 1,000 gf/15 mm or more, more preferably 2,000 gf/15 mm or more, and still more preferably 3,000 gf/15 mm or more. Furthermore, the peel strength after the wet heat treatment is preferably 300 gf/15 mm or more, more preferably 1,500 gf/15 mm or more, still more preferably 2,000 gf/15 mm or more, and particularly preferably 2,500 gf/15 mm or more. It is to be noted that the peel strength before the wet heat treatment may be 6,000 gf/15 mm or less. Also, the peel strength after the wet heat treatment may be 5,000 gf/15 mm or less.

Configuration of Multilayer Structure

The multilayer structure of the present invention is not particularly limited as long as it has: the laminate including at least two layers (Y), the layers (Y) being provided on both faces of the base (X); and the layers (Z) laminated via each of the adhesive layers (I) on both faces of the laminate, in which a total thickness of all layers is 15 μm or more and 120 μm or less. The multilayer structure of the present invention may include an other layer, may consist of only the base (X), the layers (Y), the adhesive layers (I), and the layers (Z), or may consist of only the base (X), the layers (Y), the layer (W), the adhesive layers (I), and the layers (Z). Specific examples of the configuration of the multilayer structure of the present invention are shown below, but a plurality of the specific examples may be combined into a configuration. As referred to herein, “/” means “being directly laminated”. It is to be noted that a suitable mode of the laminate is as described above.
(1) layer (Z)/adhesive layer (I)/laminate/adhesive layer (I)/layer (Z)
(2) easily adhered layer (EA)/layer (Z)/adhesive layer (I)/laminate/adhesive layer (I)/layer (Z)/easily adhered layer (EA)

Method for Producing Multilayer Structure

Since the matter described regarding the multilayer structure of the present invention can be applied to a production method of the present invention, overlapping descriptions may be omitted. Also, the matter described regarding the production method of the present invention can be applied to the multilayer structure of the present invention.

As the method for producing the multilayer structure of the present invention, a production method including: a step (I) of forming precursor layers of the layers (Y) on both faces of the base (X) by applying a coating liquid (S) containing: a metal oxide (A), an inorganic phosphorus compound (BI), and a solvent, and removing the solvent; a step (II) of forming the layers (Y) by subjecting the precursor layers of the layers (Y) to a heat treatment; and a step (III) of laminating the layers (Z) via each of the adhesive layers (I), with the laminate obtained after the step (II) may be exemplified. In addition, in a case in which a multilayer structure provided with an easily adhered layer (EA) is to be produced, the production method may include a step (IV) of laminating the easily adhered layer (EA) on the surface of on the layer (Z). Furthermore, in a case in which a multilayer structure containing an organic phosphorus compound (BO) or a polymer (F) is to be produced, the production method may include blending the organic phosphorus compound (BO) or the polymer (F) in the coating liquid (S) to be used in the step (I); or a step (IV) of preparing a coating liquid (T) containing the organic phosphorus compound (BO) or the polymer (F), and applying the coating liquid (T) onto the surface of the precursor layer of the layer (Y) obtained in the step (I), or on the surface of the layer (Y) obtained in the step (II). It is to be noted that in a case in which an adhesive layer (AC) is provided between the base (X) and the layer (Y), the production method may include before the step (I), a step of providing the adhesive layer (AC) on the base (X).

Step (I)

In the step (I), after the coating liquid (S) containing the metal oxide (A), the inorganic phosphorus compound (BI), and the solvent is applied onto the base (X), the solvent is eliminated to form precursor layers of the layers (Y). The coating liquid (S) is obtained by mixing the metal oxide (A), the inorganic phosphorus compound (BI), and the solvent.

Specific means for preparing the coating liquid (S) is exemplified by: a procedure of mixing a dispersion liquid of the metal oxide (A), with a solution containing the inorganic phosphorus compound (BI); a procedure of adding the inorganic phosphorus compound (BI) to a dispersion liquid of the metal oxide (A), followed by mixing; and the like. A temperature in the mixing is preferably 50° C. or less, more preferably 30° C. or less, and still more preferably 20° C. or less. The coating liquid (S) may contain other compound(s) (for example, the organic phosphorus compound (BO) and/or the polymer (F)), and as needed, at least one type of acid compound (Q) selected from the group consisting of acetic acid, hydrochloric acid, nitric acid, trifluoroacetic acid, and trichloroacetic acid may be contained in the coating liquid (S).

The dispersion liquid of the metal oxide (A) may be prepared, for example, in accordance with a procedure employed in a well-known sol-gel technique by, for example, mixing the compound (E), water, and as needed, an acid catalyst and/or an organic solvent, thereby subjecting the compound (E) to condensation or hydrolytic condensation. In the case in which the dispersion liquid of the metal oxide (A) is obtained by subjecting the compound (E) to condensation or hydrolytic condensation, the dispersion liquid thus obtained may be subjected to a certain treatment (deflocculation in the presence of the acid compound (Q), etc.), as needed. The solvent for use in preparing the dispersion liquid of the metal oxide (A) is not particularly limited, and is preferably: an alcohol such as methanol, ethanol, or isopropanol; water; or a mixed solvent of the same.

The solvent for use in the solution containing the inorganic phosphorus compound (BI) may be appropriately selected depending on the type of the inorganic phosphorus compound (BI), and water is preferably included. As long as dissolution of the inorganic phosphorus compound (BI) is not inhibited, the solvent may contain an organic solvent (for example, an alcohol such as methanol).

A solid content concentration of the coating liquid (S) is, in light of storage stability of the coating liquid and coating characteristics onto the base, preferably 1 to 20% by mass, more preferably 2 to 15% by mass, and still more preferably 3 to 10% by mass. The solid content concentration can be calculated by, for example, dividing a mass of a solid content remaining after evaporation of the solvent of the coating liquid (S), by a mass of the coating liquid (S) which had been subjected to the treatment.

The coating liquid (S) has a viscosity as measured, at a temperature upon being applied, by using a Brookfield rotational viscometer (SB-type viscometer: rotor No. 3, speed of rotation: 60 rpm) of preferably 3,000 mPa·s or less, more preferably 2,500 mPa·s or less, and still more preferably 2,000 mPa·s or less. Due to the viscosity being 3,000 mPa·s or less, levelling of the coating liquid (S) may improve, whereby the multilayer structure much superior in the appearance can be obtained. In addition, the viscosity of the coating liquid (S) is preferably 50 mPa·s or more, more preferably 100 mPa·s or more, and still more preferably 200 mPa·s or more.

In the coating liquid (S), a molar ratio, aluminum atom: phosphorus atom, of the aluminum atom to the phosphorus atom preferably falls within the range of 1.0:1.0 to 3.6:1.0, more preferably falls within the range of 1.1:1.0 to 3.0:1.0, and particularly preferably falls within the range of 1.11:1.00 to 1.50:1.00. The molar ratio of the aluminum atom to the phosphorus atom can be calculated by performing X-ray fluorescence spectrometry of a dry matter of the coating liquid (S).

A procedure for applying the coating liquid (S) is not particularly limited, and a well-known procedure can be adopted. Examples of the applying procedure include casting, dipping, roll coating, gravure coating, screen printing, reverse coating, spray coating, kiss coating, die coating, metering rod coating, chamber doctor coating, curtain coating, bar coating, and the like.

A procedure for eliminating the solvent (drying treatment) after applying the coating liquid (S) is not particularly limited, and a well-known drying procedure can be adopted. The drying procedure is exemplified by hot-air drying, hot roll contact drying, infrared heating, microwave heating, and the like.

A drying temperature is preferably lower than the incipient fluidization temperature of the base (X). The drying temperature after applying the coating liquid (S) may be, for example, about 60 to 180° C., and is more preferably 60° C. or more and less than 140° C., still more preferably 70° C. or more and less than 130° C., and particularly preferably 80° C. or more and less than 120° C. A drying time period is not particularly limited, and is preferably 1 sec or more and less than 1 hour, more preferably 5 sec or more and less than 15 min, and still more preferably 5 sec or more and less than 300 sec. In particular, in the case in which the drying temperature is 100° C. or more (for example, 100 to 140° C.), the drying time period is preferably 1 sec or more and less than 4 min, more preferably 5 sec or more and less than 4 min, and still more preferably 5 sec or more and less than 3 min. In the case in which the drying temperature is below 100° C. (for example, 60 to 99° C.), the drying time period is preferably 3 min or more and less than 1 hour, more preferably 6 min or more and less than 30 min, and still more preferably 8 min or more and less than 25 min. When conditions of the drying treatment of the coating liquid (S) fall within the above range, the multilayer structure having more favorable gas barrier properties tends to be obtained. By eliminating the solvent via the drying, the precursor layer of the layer (Y) is formed.

In order to laminate the layers (Y) on both faces of the base (X), a first layer (precursor layer of the first layer (Y)) may be formed by applying the coating liquid (S) onto one face of the base (X) followed by elimination of the solvent, and thereafter a second layer (precursor layer of the second layer (Y)) may be formed by applying the coating liquid (S) onto the other face of the base (X) followed by elimination of the solvent. The compositions of the coating liquids (S) to be applied onto respective faces may be the same or different. Alternatively, by applying the coating liquid (S) onto both faces of the base (X) at once, followed by elimination of the solvent, the precursor layers of two layers (Y) may be simultaneously formed.

Step (II)

In the step (II), the layers (Y) are formed by subjecting the precursor layers of the layers (Y), which were formed in the step (II), to a heat treatment. In the step (II), a reaction in which the reaction product (D) is produced proceeds. In order to allow such a reaction to proceed sufficiently, a heat treatment temperature is preferably 140° C. or more, more preferably 170° C. or more, still more preferably 180° C. or more, and particularly preferably 190° C. or more. A low heat treatment temperature requires a longer time period for obtaining a sufficient degree of reaction, thus resulting in a decrease in productivity. The heat treatment temperature may vary depending on e.g., the type of the base (X). For example, in the case of using a thermoplastic resin film made of a polyamide resin as the base (X), the heat treatment temperature is preferably 270° C. or less. Meanwhile, in the case of using a thermoplastic resin film made of a polyester resin as the base (X), the heat treatment temperature is preferably 240° C. or less. The heat treatment may be carried out in an air atmosphere, a nitrogen atmosphere, an argon atmosphere, or the like. A time period of the heat treatment is preferably 1 sec to 1 hour, more preferably 1 sec to 15 min, and still more preferably 5 to 300 sec.

The step (II) preferably includes a first heat treatment step (II-1) and a second heat treatment step (II-2). In the case in which the heat treatment is carried out by more than two steps, the temperature of the heat treatment in the second step (hereinafter, the second heat treatment) is preferably higher than the temperature of the heat treatment in the first step (hereinafter, the first heat treatment), more preferably higher than the first heat treatment temperature by 15° C. or more, still more preferably higher by 20° C. or more, and particularly preferably higher by 30° C. or more.

Furthermore, the heat treatment temperature of the step (II) (the first heat treatment temperature, in the case of the heat treatment including two or more steps) is, in light of enabling the multilayer structure to be obtained having favorable characteristics, preferably higher than the drying temperature in the step (I), more preferably higher by 30° C. or more, still more preferably higher by 50° C. or more, even more preferably higher by 55° C. or more, and particularly preferably higher by 60° C. or more.

In the case of carrying out the heat treatment of the step (II) with two or more steps, the first heat treatment temperature is preferably 140° C. or more and less than 200° C., and the second heat treatment temperature is more preferably 180° C. or more and 270° C. or less, while the second heat treatment temperature is preferably higher than the first heat treatment temperature, more preferably higher by 15° C. or more, and still more preferably higher by 25° C. or more. In particular, in the case of the heat treatment temperature being 200° C. or more, the time period of the heat treatment is preferably 0.1 sec to 10 min, more preferably 0.5 sec to 15 min, and still more preferably 1 sec to 3 min. In the case of the heat treatment temperature being below 200° C., the time period of the heat treatment is preferably 1 sec to 15 min, more preferably 5 sec to 10 min, and still more preferably 10 sec to 5 min.

Step (III)

In the step (III), the laminate obtained after the step (II) is laminated with the layers (Z) via each of the adhesive layers (I). A procedure of laminating the layers (Z) via each of the adhesive layers (I), with the laminate may be performed by a well-known process. For example, lamination can be executed by: applying a two-component adhesive on the layer (Z) or the laminate; eliminating the solvent to form the adhesive layer (I); and thereafter laminating by a well-known process.

In order for the layers (Z) to be laminated on both faces of the laminate via each of the adhesive layers (I), for example, lamination can be executed by: applying a two-component adhesive onto the layer (Z) followed by elimination of the solvent and lamination by a well-known procedure; and then applying a two-component adhesive onto another layer (Z) followed by elimination of the solvent and lamination on the other face by a well-known procedure. The compositions of the adhesives to be applied onto respective faces may be the same or different. Two adhesive layers (I) may be simultaneously laminated, or two layers (Z) may be simultaneously laminated.

Step (IV)

In the case in which the multilayer structure of the present invention has the easily adhered layer (EA), the step (IV) is carried out before or after the step (III). In the step (IV), after the coating liquid (T) is applied onto the layer (Z), the solvent is eliminated, whereby the easily adhered layer (EA) is formed. As the coating liquid (T), a commercially available member (for example, adhesive, etc.) may be used directly or as a mixture with a solvent.

As the member for use in the coating liquid (T), the adhesive exemplified for the easily adhered layer (EA) described above can be suitably used. The solvent which may be used in the coating liquid (T) is not particularly limited, and may be appropriately selected depending on a principal component thereof. In a case in which the principal component is highly soluble in an organic solvent, an organic solvent such as ethyl acetate, butyl acetate, toluene, methyl ethyl ketone, methanol, or ethanol can be used. Moreover, in a case in which the principal component is water soluble or water dispersible, water or a mixed solvent of water/alcohol, etc., can be used. These solvents may be used alone, or two or more types thereof may be used as a mixture.

A solid content concentration in the coating liquid (T) is, in light of storage stability and/or coating characteristics of the solution, preferably 0.01 to 60% by mass, more preferably 0.1 to 50% by mass, and still more preferably 0.2 to 40% by mass. The solid content concentration can be determined by a process similar to the process described in regard to the coating liquid (S).

Similarly to the applying of the coating liquid (S), a procedure for applying the coating liquid (T) is not particularly limited, and a well-known procedure may be employed.

With respect to conditions of a procedure for eliminating the solvent (drying treatment) after applying the coating liquid (T) in the step (IV), it is possible to adopt the conditions of a procedure similar to those of the drying treatment after applying the coating liquid (S) in the step (I).

The step (IV) may be carried out either before or after the step (III). In the case in which the step (IV) is carried out before the step (III), the step (III) is carried out such that, after the easily adhered layer (EA) is laminated beforehand on the layer (Z), the face of the layer (Z) on which the easily adhered layer (EA) has not been laminated comes into contact with the adhesive layer (I). In the case in which the step (IV) is carried out after the step (III), step (IV) is carried out such that the easily adhered layer (EA) is laminated on the exposed surface of the layer (Z).

Step (V)

In the case in which the organic phosphorus compound (BO), the polymer (F), and/or other component(s) are used in the production method described above, a step (V) may be also included in which a coating liquid (U) obtained by mixing the organic phosphorus compound (BO), the polymer (F), and/or the other component(s) and the solvent is applied onto: the precursor layer of the layer (Y) obtained in the step (I); the layer (Y) obtained in the step (II); or the precursor layer of the layer (Y) after the step (II-1), followed by the drying treatment. In the case in which the step (V) is carried out after the step (II-1), the step (II-2) is preferably carried out after the drying treatment in the step (V).

The solvent for use in the coating liquid (U) may be appropriately selected depending on types of the organic phosphorus compound (BO), the polymer (F), and/or the other component(s), and is preferably: an alcohol such as methanol, ethanol, or isopropanol; water; or a mixed solvent of the same.

A solid content concentration in the coating liquid (U) is, in light of storage stability and/or coating characteristics of the solution, preferably 0.01 to 60% by mass, more preferably 0.1 to 50% by mass, and still more preferably 0.2 to 40% by mass. The solid content concentration can be determined by a process similar to the process described in regard to the coating liquid (S).

Similarly to the applying of the coating liquid (S), a procedure for applying the coating liquid (U) is not particularly limited, and a well-known procedure may be employed.

With respect to conditions of a procedure for eliminating the solvent (drying treatment) after applying the coating liquid (U) in the step (V), a similar procedure can be adopted with conditions of the drying treatment after applying the coating liquid (S) in the step (I).

Electronic Device

An electronic device utilizing the multilayer structure of the present invention is provided with an electronic device main body, and a protective sheet for protecting a surface of the electronic device main body. The protective sheet for an electronic device of the present invention includes the multilayer structure of the present invention. The protective sheet for an electronic device of the present invention may be configured with only the multilayer structure of the present invention, or may be configured with the multilayer structure of the present invention and other member(s).

The electronic device of the present invention may be a photovoltaic device, an information display device, or an illuminating device. Examples of the photovoltaic device include various types of solar cells, and other photovoltaic devices. Examples of the information display device include liquid crystal displays, organic EL displays, plasma displays, electronic papers, and other information display devices. Examples of the illuminating device include LED lamps, organic EL lamps, and other illuminating devices.

The electronic device of the present invention can be particularly preferably used as a flexible electronic device. The flexible electronic device as referred to herein means an electronic device having flexibility, being an electronic device capable of maintaining its function even if being flexed. Whether the electric device of the present invention is the flexible electronic device can be decided, for example, based on whether delamination and/or bending was caused as described in Examples, when an electronic device in a sheet form is rolled up to give a roll shape having an internal diameter of 7 cm.

The protective sheet including the multilayer structure is superior in gas barrier properties and water vapor barrier properties. Furthermore, the protective sheet has high transparency. Thus, an electronic device accompanied by high transmittivity of light and less deterioration even in a severe environment can be obtained by using the protective sheet including the multilayer structure.

The multilayer structure can be used also as a film referred to as a substrate film, such as a substrate film for LCD, a substrate film for organic EL, or a substrate film for electronic paper. In such a case, the multilayer structure may serve as both the substrate and the protective sheet. Furthermore, an intended electronic device which should be protected by the protective sheet is not limited to the above illustration, and may be, for example, an IC tag, an optical communication device, a fuel cell, or the like.

The protective sheet may also include a surface protective layer provided on one surface of the multilayer structure. As the surface protective layer, a layer formed from a resin which is less likely to get scratched is preferred. In addition, a surface protective layer of a device, such as a solar cell, which may be utilized out of doors is preferably formed from a resin having superior weather resistance (for example, light resistance). Moreover, when a face which requires light transmission is to be protected, a surface protective layer having high translucency is preferred. Examples of materials of the surface protective layer (surface protective film) include acrylic resins, polycarbonate, polyethylene terephthalate, polyethylene naphthalate, ethylene-tetrafluoroethylene copolymers (ETFE), polytetrafluoroethylene, 4-fluoroethylene-perchloroalkoxy copolymers, 4-fluoroethylene-6-fluoropropylene copolymers, 2-ethylene-4-fluoroethylene copolymers, poly 3-fluorochloroethylene, polyvinylidene fluoride, polyvinyl fluoride, and the like. Of these, including the ethylene-tetrafluoroethylene copolymer is preferred in light of weather resistance and translucency.

In order to improve durability of the surface protective layer, various types of additives (for example, an ultraviolet ray-absorbing agent) may be added to the surface protective layer. One preferred example of the surface protective layer having superior weather resistance is an acrylic resin layer to which an ultraviolet ray-absorbing agent has been added. The ultraviolet ray-absorbing agent is exemplified by benzotriazole-based, benzophenone-based, salicylate-based, cyanoacrylate-based, nickel-based, and triazine-based ultraviolet ray-absorbing agents, but not limited thereto. In addition, another stabilizer, a light stabilizer, an antioxidant, etc., may be used for blending.

A configuration of the protective sheet is not particularly limited, and for example, configurations as in the following may be suitably used.
(1) multilayer structure
(2) ETFE layer/adhesive layer/multilayer structure
As the adhesive layer, EVA is suitably used.

The electronic device main body is preferably sealed by a sealant. The sealant can serve as a protective member of the electronic device. The sealant is not particularly limited, and one generally used as a sealant for an electronic device may be used. As the sealant, an ethylene-vinyl acetate copolymer (EVA), a polyolefin elastomer, polyvinylbutyral, an ionomer, and the like are exemplified, but the sealant is not particularly limited thereto. In light of cost, EVA is suitably used.

It is preferred that the protective sheet for an electronic device of the present invention is directly joined to the sealant, in light of enabling reducing a thickness of a resultant electric device and thereby enabling an improvement in flexibility, and in light of simplification of a process for producing the electronic device. In the case in which the protective sheet is joined to the sealant for sealing the electronic device main body, the protective sheet preferably includes a resin layer for joining, the resin having high adhesiveness to the sealant. In other words, it is preferred that the multilayer structure of the present invention and the sealant are directly laminated. Particularly, in the case in which the sealant is formed from an ethylene-vinyl acetate copolymer, the exposed surface of the multilayer structure of the present invention is preferably provided with the easily adhered layer (EA). It is to be noted that each layer constituting the protective sheet may be adhered by using a well-known adhesive and/or the adhesive layer described above.

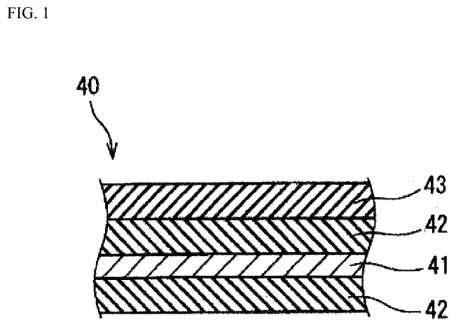

With respect to one example of the electronic device of the present invention, a partial cross sectional view is presented in FIG. 1. An electronic device 40 shown in FIG. 1 includes an electronic device main body 41, a sealant 42 for sealing the electronic device main body 41, and a protective sheet (including a multilayer structure) 43 for protecting a surface of the electronic device main body 41. The sealant 42 covers an entire surface of the electronic device main body 41. The protective sheet 43 is provided on one surface of the electronic device main body 41 via the sealant 42. A protective sheet may be provided also on a surface on the side opposite to the surface on which the protective sheet 43 has been provided. In such a case, the protective sheet provided on the opposite side surface may be identical to or different from the protective sheet 43. The protective sheet 43 is acceptable as long as it is provided in a manner to enable protection of the surface of the electronic device 41, and thus the protective sheet 43 may be provided on the electronic device main body 41 via an other member such as the sealant 42, or may be provided directly on the surface of the electronic device main body 41.

The electronic device main body 41 is not particularly limited, and examples thereof include: photovoltaic devices such as solar cells; information display devices such as organic EL displays, liquid crystal displays, and electronic papers; illuminating devices such as organic EL light-emitting elements; and the like. The sealant 42 is an optional member which is added ad libitum depending on the type, the intended usage, etc., of the electronic device main body 41. Examples of the sealant 42 include ethylene-vinyl acetate copolymers, polyvinylbutyral, and the like.

One preferred example of the electronic device main body 41 is a solar cell. The solar cell is exemplified by a silicon solar cell, a compound semiconductor solar cell, an organic solar cell, a perovskite solar cell, and the like. Examples of the silicon solar cell include monocrystalline silicon solar cells, polycrystalline silicon solar cells, amorphous silicon solar cells, and the like. Examples of the compound semiconductor solar cell include III-V group compound semiconductor solar cells, II-VI group compound semiconductor solar cells, multi-element compound semiconductor solar cells such as CIS and CIGS, and the like. Examples of the organic solar cell include organic thin film solar cells, dye-sensitized solar cells, and the like. Also, the solar cell may be either an integrated solar cell in which a plurality of unit cells are connected in series, or may not be an integrated solar cell.

The electronic device main body 41 can be produced by a roll-to-roll process, as generally referred to, depending on its type. In the roll-to-roll process, a flexible substrate (for example, a stainless substrate, a resin substrate, etc.) wound on a feeding roll is fed, and an element is formed on this substrate, whereby the electronic device main body 41 is produced. This electronic device main body 41 is wound by a wind-up roll. In this case, it is desired that the protective sheet 43 is also prepared in the form of a long flexible sheet, more specifically in the form of a wound long sheet. In one example, the protective sheet 43 fed from a feeding roll is laminated on the electronic device main body 41 before being wound by the wind-up roll, thereby being wound together with the electronic device main body 41. In one other example, the electronic device main body 41 wound by the wind-up roll may be fed again from the roll and laminated with the protective sheet 43. In one preferred example of the present invention, the electronic device per se has flexibility.

The protective sheet 43 includes the multilayer structure of the present invention. The protective sheet 43 may be constituted from only the multilayer structure. Alternatively, the protective sheet 43 may include the multilayer structure and an other member (for example, an other layer (J)) laminated to the multilayer structure. The protective sheet 43 is not particularly limited in terms of its thickness and material, as long as it is a laminate having a layer shape and being suited for protection of the surface of the electronic device, and includes the multilayer structure described above.

The configuration of the electronic device of the present invention is not particularly limited, and in light of usability as a flexible electronic device, modes shown below may be preferred.
(1) protective sheet/sealant/electronic device main body/sealant/protective sheet
(2) protective sheet/adhesive layer/sealant/electronic device main body/sealant/adhesive layer/protective sheet

As the sealant, EVA is suitably used. Furthermore, as the adhesive layer, one similar to the adhesive layer (I) may be used.

### EXAMPLES

Next, the present invention is more specifically described by way of Examples, but the present invention is not in any way limited to these Examples, and numerous modifications can be made by one of ordinary skill in the art within a scope of the technical idea of the present invention. Analyses and evaluations in Examples and Comparative Examples below were conducted as in the following.

Materials Used in Examples and Comparative Examples
PET12: biaxially stretched polyethylene terephthalate film; manufactured by Toray Industries, Inc., “Lumirror (trademark) P60” (trade name), thickness: 12 μm
PET25: biaxially stretched polyethylene terephthalate film; manufactured by Toray Industries, Inc., “Lumirror (trademark) 5105” (trade name), thickness: 25 μm
PET50: biaxially stretched polyethylene terephthalate film; manufactured by Toray Industries, Inc., “Lumirror (trademark) T60” (trade name), thickness: 50 μm
PET75: biaxially stretched polyethylene terephthalate film; manufactured by Toray Industries, Inc., “Lumirror (trademark) T60” (trade name), thickness: 75 μm
PET2: biaxially stretched polyethylene terephthalate film; manufactured by Toray Industries, Inc., “Lumirror (trademark) #2-F51” (trade name), thickness: 2 μm
Dinareo (registered trademark) PRC-002: acrylic coating agent; manufactured by Toyochem Co., Ltd., “Dinareo (registered trademark) PRC-002” (trade name), solid content concentration: 20 to 30%
EVA500: ethylene-vinyl acetate copolymer sheet (sealing sheet for solar cells), vinyl acetate unit content: 10.5 mol %, ethylene unit content: 89.5 mol %, thickness: 500 μm
EVA100: ethylene-vinyl acetate copolymer film, vinyl acetate unit content: 10.5 mol %, ethylene unit content: 89.5 mol %, thickness: 100 μm
ETFE25: ethylene-tetrafluoroethylene copolymer film, thickness: 25 μm

Evaluation Methods

(1) Measurement of Infrared Absorption Spectrum

The measurement was conducted on layers (Y) of laminates obtained in the Examples and the Comparative Examples by attenuated total reflection using a Fourier transform infrared spectrophotometer. Measurement conditions were as in the following.
apparatus: Spectrum One manufactured by PerkinElmer, Inc.
mode of measurement: attenuated total reflection
region of measurement: 800 to 1,400 cm⁻¹

(2) Shrinkage Percentage in MD Direction

The laminates and the layers (Y) obtained in the Examples and the Comparative Examples were cut away to give pieces of 12 cm×12 cm, and a 6 cm×6 cm grid pattern was drawn on a central portion such that each grid was about 1 cm. Then, the length of the grid pattern being parallel to an MD direction was measured with calipers. Subsequently, each multilayer structure was left to stand in a dryer at 160° C. for 30 min and taken out, and then the length of the grid pattern being parallel to the MD direction was measured again with calipers. The shrinkage percentages of respective grids were calculated from the change in length of the grids on the multilayer structure before and after being left to stand in the dryer, and averaging the shrinkage percentages led to the shrinkage percentage in the MD direction. Then, the thermal shrinkage percentage of the multilayer structure in the MD direction was determined as TS, and the thermal shrinkage percentage in the MD direction of the layer (Z) constituting the multilayer structure was determined as TS_{Z}, and the ratio (TS_{Z}/TS) of the thermal shrinkage percentage in the MD direction was calculated.

(3) Thickness

The multilayer structures obtained in the Examples and the Comparative Examples were cut by using a focused ion beam (FIB) to prepare slices for inspection of cross sections. Thus prepared slices were secured onto a sample stage with a carbon tape and subjected to platinum ion sputtering at an accelerating voltage of 30 kV for 30 sec. Each cross section of the multilayer structures was observed using a field-emission transmission electron microscope to determine the thicknesses of each layer and the thickness of the multilayer structure. The measurement conditions were as in the following.
apparatus: JEM-2100F, manufactured by JEOL, Ltd.
accelerating voltage: 200 kV
magnification: ×250,000

(4) Moisture Permeability

Each of the multilayer structures obtained in the Examples and the Comparative Examples was placed in a water vapor transmission rate testing apparatus, and the moisture permeability (water vapor transmission rate) was measured by a differential pressure method in accordance with ISO15106-5:2015. Measurement conditions were as in the following.
apparatus: DELTAPERM manufactured by Technolox Ltd.
temperature: 40° C.
humidity on water vapor feed side: 90% RH

(5) Peel Strength

Vacuum laminate was performed using two pieces of each of the multilayer structures obtained in the Examples and the Comparative Examples and EVA500 under the following conditions to produce a measurement sample of “multilayer structure/EVA500/multilayer structure”.

Conditions of Vacuum Lamination
vacuum lamination apparatus: 1522N, manufactured by Nisshinbo Mechatronics Inc.
vacuuming time period: 8 min
temperature: 160° C.
time period: 30 min
pressure: 30 kPa

From each measurement sample thus obtained, a test piece of 13 cm in a longitudinal direction (MD direction) and 10 mm in a width direction (TD direction) was cut out, and the test piece thus cut out was subjected to the measurement of the peel strength before and after the wet heat treatment. With respect to the peel strength, T-type peel strength (adhesive force per with of 10 mm) was measured in accordance with JIS K 6854-3:1999. The peel strength was measured five times under the following conditions, and an average value of these was determined. It is to be noted that an interface peeled by this measuring method is an interface having the smallest peel strength in the measurement sample, and peeling of the interface between the EVA layer and the multilayer structure was confirmed on all samples except for Comparative Example 6. As for Comparative Example 6, peeling of the interface between the base (X) and the layer (Y) was confirmed.

Conditions of T-Type Peel Test
apparatus: Autograph AGS-H, manufactured by Shimadzu Corporation
peeling speed: 250 mm/min
temperature: 23° C.
humidity: 50% RH

Conditions of Wet Heat Treatment
apparatus: Constant Temperature and Humidity Chamber PR-4J, manufactured by ESPEC
temperature: 85° C.
humidity: 85% RH
time period: 300 hrs

(6) Roll Formability (Flexibility)

The multilayer structures obtained in the Examples and the Comparative Examples were cut out to have a length (MD direction) of 29.7 cm and a width (TD direction) of 21 cm, and rolled up in the lengthwise direction to give a roll shape having a diameter of 2 cm, and then a rubber band having an internal diameter of 38 cm, a thickness of 1.1 mm, and a cut width of 1 1 mm (O'Band #16, manufactured by KYOWA Limited) was placed at a center of the roll. Thereafter rolling force was released to give a state of maintaining a roll shape with only the rubber band. Subsequently, diameters at both ends were measured. This measurement was conducted five times, and an average of values at ten points in total was calculated. With respect to the average value, evaluations were made as: A for the case of being less than 4.2 cm; B for the case of extension to be 4.2 cm or more and less than 4.5 cm; and C for the case of extension to be 4.5 cm or more.

Production Example of Coating Liquid (S-1)

A temperature of 230 parts by mass of distilled water was elevated to 70° C. with stirring. To this distilled water were added dropwise 88 parts by mass of triisopropoxyaluminum over 1 hour, and hydrolytic condensation was performed by gradually elevating the liquid temperature to 95° C. and allowing isopropanol generated to be evaporated off. To the liquid thus obtained, 4.0 parts by mass of a 60% by mass aqueous nitric acid solution were added, followed by stirring at 95° C. for 3 hrs to permit deflocculation of aggregates of particles of a hydrolytic condensation product. Thereafter, this liquid was concentrated such that a solid content concentration in terms of aluminum oxide equivalent became 10% by mass, whereby a solution was obtained. To 22.50 parts by mass of the solution thus obtained, 54.29 parts by mass of distilled water and 18.80 parts by mass of methanol were added, and the mixture was stirred to be homogenous, whereby a dispersion liquid was obtained. Subsequently, 4.41 parts by mass of a 85% by mass aqueous phosphoric acid solution were added dropwise while the liquid temperature of 15° C. was maintained and the dispersion liquid was stirred. Furthermore, 18.80 parts by mass of a methanol solution were added dropwise and the stirring was continued at 15° C. until a viscosity of 1,500 mPa·s was attained, whereby an intended coating liquid (S-1) was obtained. A molar ratio of the aluminum atom to the phosphorus atom in the coating liquid (S-1) was found to be aluminum atom:phosphorus atom=1.15:1.00.

Production Example of Coating Liquid (T-1)

Ten parts by mass of Dinareo (registered trademark) PRC-002 and 90 parts by mass of ethyl acetate were mixed, and the resulting mixture was stirred at room temperature for 30 min to give a coating liquid (T-1) having a solid content concentration of 3.0%.

### Example 1

Using PET25 as the base (X), the coating liquid (S-1) was applied with a bar coater onto one face of the base such that the thickness after drying became 0.4 μm. Following drying of the film after applying at 120° C. for 3 min, a heat treatment was carried out at 180° C. for 1 min to form a precursor layer of the layer (Y) on the base. Next, onto another face of the base, the coating liquid (S-1) was applied with a bar coater such that the thickness after drying became 0.4 μm. Following drying of the film after applying at 120° C. for 3 min, a heat treatment was carried out at 180° C. for 1 min to form a precursor layer of the layer (Y) on the base. The film obtained by forming the precursor layers of the layers (Y) was subjected to a heat treatment at 210° C. for 1 min to give a laminate (1): “layer (Y) (0.4 μm)/PET25 (25 μm)/layer (Y) (0.4 μm)”. With respect to the layers (Y) of the laminate (1) thus obtained, the infrared absorption spectrum was measured according to the method described in the Evaluation Method (1) above, and maximum absorption wavenumbers (Imax) of the layers (Y) on both faces in the region of 800 to 1,400 cm⁻1 were evaluated. Moreover, with respect to the laminate (1) obtained, a thermal shrinkage percentage TS in the MD direction was measured according to the method described in the Evaluation Method (2) above. The results are shown in Table 1.

As the layer (Z), PET12 was prepared. Adhesive layers (I) were formed on the surfaces of two pieces of PET12, respectively. On the adhesive layers (I), laminates (1) were laminated and aged by leaving to stand at 40° C. for 5 days to give a multilayer structure (1-1) having a configuration of “PET12/adhesive layer (I)/laminate (1)/adhesive layer (I)/PET12”. The adhesive layers (I) were each formed by: applying a two-component adhesive (“TAKELAC” (registered trademark) “A-520” (brand name) manufactured by Mitsui Chemicals, Inc., and “TAKENATE” (registered trademark) “A-50” (brand name) manufactured by Mitsui Chemicals, Inc.), with a bar coater such that the thickness after drying became 3 μm; and drying. It is to be noted that with respect to the layer (Z) employed, thermal shrinkage percentage in the MD direction TS_{Z} was measured according to the method described in the Evaluation Method (2) above. The results are shown in Table 1.

On the multilayer structure (1-1), the coating liquid (T-1) was applied with a bar coater such that the thickness after drying became 0.3 μm. An easily adhered layer (EA) was laminated by drying the film at 140° C. for 1 min, after applying. Furthermore, also onto another face of the multilayer structure (1-1), the coating liquid (T-1) was applied with a bar coater such that the thickness became 0.3 μm. The film after applying was dried at 140° C. for 1 min, whereby a multilayer structure (1-2) having a configuration of “easily adhered layer (EA)/multilayer structure (1-1)/easily adhered layer (EA)” was obtained.

With respect to the multilayer structure (1-2), the thickness, the moisture permeability, the roll formability, and the peel strength with respect to the EVA layer before and after the wet heat treatment ware evaluated according to methods described in the above Evaluation Methods (3) to (6). The results are shown in Table 2.

### Examples 2 to 9 and Comparative Examples 1 to 6

Laminates and multilayer structures were produced and evaluated by a similar method to Example 1 except that types of the base (X) and the layers (Z), and the layer configuration were changed according to Table 1 and 2. The results are shown in Table 1 and Table 2.

### Example 10

A laminate and a multilayer structure were produced and evaluated by a similar method to Example 1 except that PET12 which had been left to stand in a dryer at 160° C. for 3 min was used as the layer (Z). The results are shown in Table 1 and Table 2.

### Example 11

A laminate and a multilayer structure were produced and evaluated in a similar manner to Example 1 except that PET12 and PET25 were used as the layers (Z) to produce a multilayer structure (10-1) having a layer configuration of PET12 (layer (Z1))/adhesive layer (I)/laminate (1)/adhesive layer (I)/PET25 (layer (Z2)). The results are shown in Table 1 and Table 2.

### Comparative Example 7

A multilayer structure was produced and evaluated by a similar method to Example 1 except that after applying the coating liquid (S-1) followed by drying at 120° C. for 3 min, the heat treatment at 180° C. for 1 min and the heat treatment at 210° C. for 1 min were not carried out.

TABLE 1

| | | | | | | | | Easily adhered | | | | |
|---|---|---|---|---|---|---|---|---|---|---|---|---|
| | Base (X) | | Layer (Y) | | | Layer (Z) | | layer (EA) | | | | |
| | | single | | single | | | single | | single | | | |
| | | layer | coating | layer | | | layer | coating | layer | Thermal shrinkage | | |
| | | thickness | liquid | thickness | Imax | | thickness | liquid | thickness | percentage in MD direction | | |
| | type | (μm) | (S) | (μm) | (cm⁻¹) | type | (μm) | (T) | (μm) | TS (%) | TS_{z} (%) | TS_{z}/TS |
| Example 1 | PET25 | 25 | S-1 | 0.4 | 1,108 | PET12 | 12 | T-1 | 0.3 | 0.21 | 1.36 | 6.48 |
| Example 2 | PET12 | 12 | S-1 | 0.4 | 1,108 | PET12 | 12 | T-1 | 0.3 | 0.31 | 1.36 | 4.39 |
| Example 3 | PET25 | 25 | S-1 | 0.4 | 1,108 | PET25 | 25 | T-1 | 0.3 | 0.21 | 1.25 | 5.95 |
| Example 4 | PET75 | 75 | S-1 | 0.4 | 1,108 | PET12 | 12 | T-1 | 0.3 | 0.16 | 1.36 | 8.50 |
| Example 5 | PET25 | 25 | S-1 | 0.4 | 1,108 | PET12 | 12 | — | — | 0.21 | 1.36 | 6.48 |
| Example 6 | PET12 | 12 | S-1 | 0.4 | 1,108 | PET12 | 12 | — | — | 0.31 | 1.36 | 4.39 |
| Example 7 | PET25 | 25 | S-1 | 0.4 | 1,108 | PET25 | 25 | — | — | 0.21 | 1.25 | 5.95 |
| Example 8 | PET75 | 75 | S-1 | 0.4 | 1,108 | PET12 | 12 | — | — | 0.16 | 1.36 | 8.50 |
| Example 9 | PET25 | 25 | S-1 | 0.5 | 1,108 | PET12 | 12 | T-1 | 0.3 | 0.20 | 1.36 | 6.80 |
| Example 10 | PET25 | 25 | S-1 | 0.4 | 1,108 | PET12 | 12 | T-1 | 0.3 | 0.20 | 0.65 | 3.25 |
| Example 11 | PET25 | 25 | S-1 | 0.4 | 1,108 | PET12 | 12 | T-1 | 0.3 | 0.20 | 1.36 | 6.48 |
| | | | | | | PET25 | 25 | | | | 1.25 | 5.95 |
| Comparative | PET25 | 25 | S-1 | 0.4 | 1,108 | — | — | — | — | 0.21 | — | — |
| Example 1 | | | | | | | | | | | | |
| Comparative | PET25 | 25 | S-1 | 0.4 | 1,108 | — | — | T-1 | 0.3 | 0.21 | — | — |
| Example 2 | | | | | | | | | | | | |
| Comparative | PET25 | 25 | S-1 | 0.4 | 1,108 | PET50 | 50 | T-1 | 0.3 | 0.21 | 1.20 | 5.71 |
| Example 3 | | | | | | | | | | | | |
| Comparative | PET75 | 75 | S-1 | 0.4 | 1,108 | PET25 | 25 | T-1 | 0.3 | 0.16 | 1.25 | 7.81 |
| Example 4 | | | | | | | | | | | | |
| Comparative | PET25 | 25 | S-1 | 0.4 | 1,108 | PET2 | 2 | T-1 | 0.3 | 0.23 | 1.45 | 6.30 |
| Example 5 | | | | | | | | | | | | |
| Comparative | PET25 | 25 | S-1 | 0.4 | 1,108 | PET12 | 12 | T-1 | 0.3 | 0.21 | 1.36 | 6.48 |
| Example 6 | | | | | | | | | | | | |
| Comparative | PET25 | 25 | S-1 | 0.4 | 1,068 | PET12 | 12 | T-1 | 0.3 | 1.10 | 1.36 | 1.24 |
| Example 7 | | | | | | | | | | | | |

TABLE 2

| | | | Evaluation | | | |
|---|---|---|---|---|---|---|
| | | | Moisture | | Peel strength | |
| | Multilayer structure | | permeability | | before wet | after wet |
| | | Thickness | (40° C., 90% RH) | Roll | heat treatment | heat treatment |
| | Layer configuration | (μm) | (g/m² · day) | formability | (gf/15 mm) | |
| Example 1 | (EA)/(Z)/(I)/(Y)/(X)/(Y)/(I)/(Z)/(EA) | 56.4 | 3.5 × 10⁻³ | A | 4,000 | 3,300 |
| Example 2 | (EA)/(Z)/(I)/(Y)/(X)/(Y)/(I)/(Z)/(EA) | 43.4 | 4.1 × 10⁻³ | A | 3,800 | 3,000 |
| Example 3 | (EA)/(Z)/(I)/(Y)/(X)/(Y)/(I)/(Z)/(EA) | 82.4 | 3.5 × 10⁻³ | A | 4,700 | 4,000 |
| Example 4 | (EA)/(Z)/(I)/(Y)/(X)/(Y)/(I)/(Z)/(EA) | 106.4 | 2.8 × 10⁻³ | B | 5,000 | 4,300 |
| Example 5 | (Z)/(I)/(Y)/(X)/(Y)/(I)/(Z) | 55.8 | 3.5 × 10⁻³ | A | 1,500 | 400 |
| Example 6 | (Z)/(I)/(Y)/(X)/(Y)/(I)/(Z) | 42.8 | 4.1 × 10⁻³ | A | 1,400 | 400 |
| Example 7 | (Z)/(I)/(Y)/(X)/(Y)/(I)/(Z) | 81.8 | 3.5 × 10⁻³ | A | 1,600 | 600 |
| Example 8 | (Z)/(I)/(Y)/(X)/(Y)/(I)/(Z) | 105.8 | 2.8 × 10⁻³ | B | 1,700 | 500 |
| Example 9 | (EA)/(Z)/(I)/(Y)/(X)/(Y)/(I)/(Z)/(EA) | 56.6 | 1.3 × 10⁻³ | A | 4,000 | 3,300 |
| Example 10 | (EA)/(Z)/(I)/(Y)/(X)/(Y)/(I)/(Z)/(EA) | 56.4 | 3.5 × 10⁻³ | A | 3,600 | 2,900 |
| Example 11 | (EA)/(Z1)/(I)/(Y)/(X)/(Y)/(I)/(Z2)/(EA) | 69.6 | 3.5 × 10⁻³ | A | 4,100 | 3,400 |
| Comparative | (Y)/(X)/(Y) | 25.8 | 3.5 × 10⁻³ | A | 2,200 | 70 |
| Example 1 | | | | | | |
| Comparative | (EA)/(Y)/(X)/(Y)/(EA) | 26.4 | 3.5 × 10⁻³ | A | 2,100 | <10 |
| Example 2 | | | | | | |
| Comparative | (EA)/(Z)/(I)/(Y)/(X)/(Y)/(I)/(Z)/(EA) | 132.4 | 3.5 × 10⁻³ | C | 4,000 | 3,300 |
| Example 3 | | | | | | |
| Comparative | (EA)/(Z)/(I)/(Y)/(X)/(Y)/(I)/(Z)/(EA) | 132.4 | 2.8 × 10⁻³ | C | 5,000 | 4,300 |
| Example 4 | | | | | | |
| Comparative | (EA)/(Z)/(I)/(Y)/(X)/(Y)/(I)/(Z)/(EA) | 46.4 | 3.5 × 10⁻³ | A | 1,000 | 300 |
| Example 5 | | | | | | |
| Comparative | (EA)/(Z)/(I)/(Y)/(X)/(I)/(Z)/(EA) | 56.0 | 4.0 × 10⁻² | A | 3,800 | 2,900 |
| Example 6 | | | | | | |
| Comparative | (EA)/(Z)/(I)/(Y)/(X)/(Y)/(I)/(Z)/(EA) | 56.4 | >1.0 | A | 1,500 | <10 |
| Example 7 | | | | | | |

### Example 12

A solar cell (total layer thickness: 520 μm) having a configuration of ETFE25/EVA100/multilayer structure (1-1)/EVA100/CIGS cell/EVA100/multilayer structure (1-1) was produced by using the multilayer structure (1-2) produced in Example 1, EVA100, ETFE25, and a CIGS cell through vacuum lamination under the conditions described in the above Evaluation Method (5).

When the solar cell thus obtained was rolled up to give a roll shape having an internal diameter of 7 cm, fixed with a cord, and stored under a condition of 23° C. and 50% RH and a condition of 85° C. and 85% RH, each for one month, the solar cell exhibited favorable appearance being maintained without occurrence of delamination. In addition, the solar cell thus obtained was stored in an atmosphere of 85° C. and 85% RH for 300 hrs, and as a result of measurement of photoelectric conversion efficiencies before and after the storage, a decline rate of less than 10% was revealed.

### Comparative Example 8

A solar cell (total layer thickness: 672 μm) having a configuration of ETFE25/EVA100/multilayer structure of Comparative Example 3/EVA100/CIGS cell/EVA100/multilayer structure (C3-1) was produced in a similar manner to that of Example 9 except that the multilayer structure (easily adhered layer (EA)/PET50/adhesive layer (I)/layer (Y)/PET25/layer (Y)/adhesive layer (I)/PET50/easily adhered layer (EA)) (thickness: 132.4 μm) produced in Comparative Example 3 was used. When the solar cell thus obtained was rolled up to give a roll shape having an internal diameter of 7 cm, poor appearance was developed due to delamination and/or bending around the solar cell.

### EXPLANATION OF THE REFERENCE SYMBOLS

40 electronic device
41 electronic device main body
42 sealant
43 protective sheet (including a multilayer structure)

1. A multilayer structure comprising:
a laminate comprising a base (X) and at least two layers (Y), the layers (Y) being provided on both faces of the base (X); and
layers (Z) comprising a thermoplastic resin as a principal component and being laminated via each of adhesive layers (I) on both faces of the laminate, wherein
the at least two layers (Y) comprise a reaction product (D) of an inorganic phosphorus compound (BI) with a metal oxide (A) comprising an aluminum atom,
a thickness of the base (X) is 5 μm or more and 100 μm or less,
a thickness of each layer of the layers (Z) is 5 μm or more and 100 μm or less,
a total thickness of all layers is 15 μm or more and 120 μm or less,
the at least two layers (Y) may be identical to or different from each other,
the adhesive layers (I) provided on both faces of the laminate may be identical to or different from each other,
the layers (Z) provided on both faces of the laminate may be identical to or different from each other, and
a moisture permeability measured in accordance with ISO15106-5 is 1.0×10^{31 2} g/m²·day or less.

2. The multilayer structure according to claim 1, wherein a thermal shrinkage percentage TS in an MD direction of the laminate when heated at 160° C. for 30 min is 1.0% or less.

3. The multilayer structure according to claim 1, wherein with respect to thermal shrinkage percentages in an MD direction when heated at 160° C. for 30 min, a ratio (TS_{Z}/TS) of a thermal shrinkage percentage TS_{Z} of each of the layers (Z) to a thermal shrinkage percentage TS of the laminate is 2 or more.

4. The multilayer structure according to claim 1, further comprising an easily adhered layer (EA) laminated on at least one exposed surface side of the layers (Z).

5. The multilayer structure according to claim 4, wherein the easily adhered layer (EA) comprises an acrylic resin.

6. The multilayer structure according to claim 1, wherein the layers (Z) comprise a polyester resin.

7. A method for producing the multilayer structure according to claim 1, the method comprising:
a step (I) of forming precursor layers of the layers (Y) on both faces of the base (X) by applying a coating liquid (S) comprising: a metal oxide (A) comprising an aluminum atom; an inorganic phosphorus compound (BI); and a solvent, and removing the solvent;
a step (II) of forming the layers (Y) by subjecting the precursor layers of the layers (Y) to a heat treatment; and
a step (III) of laminating the layers (Z) via each of the adhesive layers (I), with the laminate obtained after the step (II) of forming the layers (Y).

8. A protective sheet for an electronic device, the protective sheet comprising the multilayer structure according to claim 1.

9. The protective sheet according to claim 8, which is a protective sheet for protecting a surface of a photovoltaic device, an information display device, or an illuminating device.

10. An electronic device comprising the protective sheet according to claim 8.

11. The electronic device according to claim 10, which is a flexible electronic device.
